(19) United States
(12) Patent Application Publication
(10) Pub. No.: US 2016/0327703 A1
(43) Pub. Date: Nov. 10, 2016

(54) LIGHT-EMITTING DEVICE INCLUDING PHOTOLUMINESCENT LAYER

(71) Applicant: Panasonic Intellectual Property Management Co., Ltd., Osaka (JP)

(72) Inventors: TAKU HIRASAWA, Kyoto (JP); YASUHISA INADA, Osaka (JP); YOSHITAKA NAKAMURA, Osaka (JP); AKIRA HASHIYA, Osaka (JP); MITSURU NITTA, Kyoto (JP); TAKEYUKI YAMAKI, Nara (JP)

(21) Appl. No.: 15/214,523

(22) Filed: Jul. 20, 2016

Related U.S. Application Data
(63) Continuation of application No. PCT/JP2015/000811, filed on Feb. 20, 2015.

(30) Foreign Application Priority Data
Feb. 28, 2014 (JP) 2014-037992
Jul. 29, 2014 (JP) 2014-154121

(51) Int. Cl. G02B 5/18; H01L 33/04; H01L 33/50; H01L 27/15; F21V 9/16; H01L 33/58

(52) U.S. Cl. CPC G02B 5/1809; F21V 9/16; G02B 5/1866; H01L 33/58; H01L 33/505; H01L 33/508; H01L 27/156; H01L 33/507; H01L 33/04; H01L 2933/0083; H01L 2933/0041; H01L 2933/0058

(57) ABSTRACT

A light-emitting device includes a photoluminescent layer and a light-transmissive layer. At least one of the photoluminescent layer and the light-transmissive layer has a submicron structure including at least two periodic structures. Light emitted from the photoluminescent layer includes first light having a wavelength λₐ in air and second light having a wavelength λ_{b} in air. The at least two periodic structures include a first periodic structure having a first period pₐ that satisfies λₐ/n_{wav-a}<pₐ<λₐ and a second periodic structure having a second period p_{b} that satisfies λ_{b}/n_{wav-b}<p_{b}<λ_{b}, where n_{wav-a} and n_{wav-b} denote refractive indices of the photoluminescent layer for the first light and the second light, respectively.

### BACKGROUND

1. Technical Field

The present disclosure relates to a light-emitting device including a photoluminescent layer.

2. Description of the Related Art

Optical devices, such as lighting fixtures, displays, and projectors, that output light in the necessary direction are required for many applications. Photoluminescent materials, such as those used for fluorescent lamps and white light-emitting diodes (LEDs), emit light in all directions. Thus, those materials are used in combination with optical elements such as reflectors and lenses to output light only in a particular direction. For example, Japanese Unexamined Patent Application Publication No. 2010-231941 discloses an illumination system including a light distributor and an auxiliary reflector to provide sufficient directionality.

### SUMMARY

In one general aspect, the techniques disclosed here feature a light-emitting device that includes a photoluminescent layer, and a light-transmissive layer located on the photoluminescent layer. At least one of the photoluminescent layer and the light-transmissive layer has a submicron structure including at least two periodic structures having at least projections or recesses. Light emitted from the photoluminescent layer includes first light having a wavelength λₐ in air and second light having a wavelength λ_{b} in air. The at least two periodic structures include a first periodic structure having a first period pₐ that satisfies λₐ/n_{wav-a}<pₐ<λₐ and a second periodic structure having a second period p_{b} that satisfies λ_{b}/n_{wav-b}<p_{b}<λ_{b}, where n_{wav-a} and n_{wav-b} denote refractive indices of the photoluminescent layer for the first light and the second light, respectively.

It should be noted that general or specific embodiments may be implemented as a device, an apparatus, a system, a method, or any elective combination thereof.

### BRIEF DESCRIPTION OF THE DRAWINGS

FIG. 1A is a perspective view of the structure of a light-emitting device according to an embodiment;

FIG. 1B is a fragmentary cross-sectional view of the light-emitting device illustrated in FIG. 1A;

FIG. 1C is a perspective view of the structure of a light-emitting device according to another embodiment;

FIG. 1D is a fragmentary cross-sectional view of the light-emitting device illustrated in FIG. 1C;

FIG. 2 is a graph showing the calculation results of the enhancement of light output in the front direction with varying emission wavelengths and varying a period of a periodic structure;

FIG. 3 is a graph illustrating the conditions for m=1 and m=3 in the inequality (10);

FIG. 4 is a graph showing the calculation results of the enhancement of light output in the front direction with varying emission wavelengths and varying thicknesses t of a photoluminescent layer;

FIG. 5A is a graph showing the calculation results of the electric field distribution of a mode to guide light in the x direction for a thickness t of 238 nm;

FIG. 5B is a graph showing the calculation results of the electric field distribution of a mode to guide light in the x direction for a thickness t of 539 nm;

FIG. 5C is a graph showing the calculation results of the electric field distribution of a mode to guide light in the x direction for a thickness t of 300 nm;

FIG. 6 is a graph showing the calculation results of the enhancement of light performed under the same conditions as in FIG. 2 except that the polarization of the light was assumed to be the TE mode, which has an electric field component perpendicular to the y direction;

FIG. 7A is a plan view of a two-dimensional periodic structure;

FIG. 7B is a graph showing the results of calculations performed as in FIG. 2 for the two-dimensional periodic structure;

FIG. 8 is a graph showing the calculation results of the enhancement of light output in the front direction with varying emission wavelengths and varying refractive indices of the periodic structure;

FIG. 9 is a graph showing the results obtained under the same conditions as in FIG. 8 except that the photoluminescent layer was assumed to have a thickness of 1,000 nm;

FIG. 10 is a graph showing the calculation results of the enhancement of light output in the front direction with varying emission wavelengths and varying heights of the periodic structure;

FIG. 11 is a graph showing the results of calculations performed under the same conditions as in FIG. 10 except that the periodic structure was assumed to have a refractive index nₚ of 2.0;

FIG. 12 is a graph showing the results of calculations performed under the same conditions as in FIG. 9 except that the polarization of the light was assumed to be the TE mode, which has an electric field component perpendicular to the y direction;

FIG. 13 is a graph showing the results of calculations performed under the same conditions as in FIG. 9 except that the photoluminescent layer was assumed to have a refractive index n_{wav} of 1.5;

FIG. 14 is a graph showing the results of calculations performed under the same conditions as in FIG. 2 except that the photoluminescent layer and the periodic structure were assumed to be located on a transparent substrate having a refractive index of 1.5;

FIG. 15 is a graph illustrating the condition represented by the inequality (15);

FIG. 16 is a schematic view of a light-emitting apparatus including a light-emitting device illustrated in FIGS. 1A and 1B and a light source that directs excitation light into a photoluminescent layer;

FIGS. 17A to 17D illustrate structures in which excitation light is coupled into a quasi-guided mode to efficiently output light: FIG. 17A illustrates a one-dimensional periodic structure having a period pₓ in the x direction, FIG. 17B illustrates a two-dimensional periodic structure having a period pₓ in the x direction and a period p_{y} in the y direction, FIG. 17C illustrates the wavelength dependence of light absorptivity in the structure in FIG. 17A, and FIG. 17D illustrates the wavelength dependence of light absorptivity in the structure in FIG. 17B;

FIG. 18A is a schematic view of a two-dimensional periodic structure;

FIG. 18B is a schematic view of another two-dimensional periodic structure;

FIG. 19A is a schematic view of a modified example in which a periodic structure is formed on a transparent substrate;

FIG. 19B is a schematic view of another modified example in which a periodic structure is formed on a transparent substrate;

FIG. 19C is a graph showing the calculation results of the enhancement of light output from the structure illustrated in FIG. 19A in the front direction with varying emission wavelengths and varying periods of the periodic structure;

FIG. 20 is a schematic view of a mixture of light-emitting devices in powder form;

FIG. 21 is a plan view of a two-dimensional array of periodic structures having different periods on the photoluminescent layer;

FIG. 22 is a schematic view of a light-emitting device including photoluminescent layers each having a textured surface;

FIG. 23 is a cross-sectional view of a structure including a protective layer between a photoluminescent layer and a periodic structure;

FIG. 24 is a cross-sectional view of a structure including a periodic structure formed by processing only a portion of a photoluminescent layer;

FIG. 25 is a cross-sectional transmission electron microscopy (TEM) image of a photoluminescent layer formed on a glass substrate having a periodic structure;

FIG. 26 is a graph showing the results of measurements of the spectrum of light output from a sample light-emitting device in the front direction;

FIG. 27A is a schematic view of a light-emitting device that can emit linearly polarized light of the TM mode, rotated about an axis parallel to the line direction of the one-dimensional periodic structure;

FIG. 27B is a graph showing the results of measurements of the angular dependence of light output from the sample light-emitting device rotated as illustrated in FIG. 27A;

FIG. 27C is a graph showing the results of calculations of the angular dependence of light output from the sample light-emitting device rotated as illustrated in FIG. 27A;

FIG. 27D is a schematic view of a light-emitting device that can emit linearly polarized light of the TE mode, rotated about an axis parallel to the line direction of the one-dimensional periodic structure;

FIG. 27E is a graph showing the results of measurements of the angular dependence of light output from the sample light-emitting device rotated as illustrated in FIG. 27D;

FIG. 27F is a graph showing the results of calculations of the angular dependence of light output from the sample light-emitting device rotated as illustrated in FIG. 27D;

FIG. 28A is a schematic view of a light-emitting device that can emit linearly polarized light of the TE mode, rotated about an axis perpendicular to the line direction of the one-dimensional periodic structure;

FIG. 28B is a graph showing the results of measurements of the angular dependence of light output from the sample light-emitting device rotated as illustrated in FIG. 28A;

FIG. 28C is a graph showing the results of calculations of the angular dependence of light output from the sample light-emitting device rotated as illustrated in FIG. 28A;

FIG. 28D is a schematic view of a light-emitting device that can emit linearly polarized light of the TM mode, rotated about an axis perpendicular to the line direction of the one-dimensional periodic structure;

FIG. 28E is a graph showing the results of measurements of the angular dependence of light output from the sample light-emitting device rotated as illustrated in FIG. 28D;

FIG. 28F is a graph showing the results of calculations of the angular dependence of light output from the sample light-emitting device rotated as illustrated in FIG. 28D;

FIG. 29 is a graph showing the results of measurements of the angular dependence of light (wavelength: 610 nm) output from the sample light-emitting device;

FIG. 30 is a schematic perspective view of a slab waveguide;

FIG. 31A is a schematic perspective view of a light-emitting device, and FIG. 31B is a schematic perspective view of a light-emitting device;

FIG. 32A is a plan view of a square grid pattern of a two-dimensional periodic structure, FIG. 32B is a plan view of a checkered pattern (checked pattern) of a two-dimensional periodic structure, and FIG. 32C is a graph illustrating the distribution of spatial frequency intensity (a square of the absolute value of amplitude) obtained by Fourier transformation of the pattern in FIG. 32A;

FIG. 33A is a plan view of a pattern of a two-dimensional periodic structure including periodic structures having different directions of periodicity, FIG. 33B is a graph illustrating the distribution of spatial frequency intensity of a periodic structure obtained by Fourier transformation of the pattern in FIG. 33A, and FIG. 33C is a schematic perspective view of a light-emitting device that includes a light-transmissive layer (periodic structure) having the pattern in FIG. 33A;

FIGS. 34A and 34B are plan views of patterns of a two-dimensional periodic structure including periodic structures having different directions of periodicity;

FIG. 35A is a plan view of a pattern obtained as a logical sum of the patterns in FIGS. 34A and 34B, and FIG. 35B is a graph illustrating the distribution of spatial frequency intensity of a periodic structure obtained by Fourier transformation of the pattern in FIG. 35A;

FIGS. 36A to 36E are schematic cross-sectional views of the structure of the light-emitting devices each having periodic structures; and

FIG. 37A is a plan view of a pattern of a two-dimensional periodic structure including periodic structures having different periods, and FIG. 37B is a graph illustrating the distribution of spatial frequency intensity obtained by Fourier transformation of the pattern in FIG. 37A.

### DETAILED DESCRIPTION

The present disclosure includes the following light-emitting devices and light-emitting apparatuses:

[Item 1] A light-emitting device including

a photoluminescent layer,

a light-transmissive layer located on or near the photoluminescent layer, and

a submicron structure that is formed on at least one of the photoluminescent layer and the light-transmissive layer and that extends in a plane of the photoluminescent layer or the light-transmissive layer,

wherein the submicron structure has projections or recesses,

light emitted from the photoluminescent layer includes first light having a wavelength λₐ in air, and

the distance Dᵢₙₜ between adjacent projections or recesses and the refractive index n_{wav-a} of the photoluminescent layer for the first light satisfy λₐ/n_{wav-a}<Dᵢₙₜ<λₐ.

[Item 2] The light-emitting device according to Item 1, wherein the submicron structure includes at least one periodic structure having at least the projections or recesses, and the at least one periodic structure includes a first periodic structure having a period pₐ that satisfies λₐ/n_{wav-a}<pₐ<λₐ.
[Item 3] The light-emitting device according to Item 1 or 2, wherein the refractive index nₜ₋ₐ of the light-transmissive layer for the first light is lower than the refractive index n_{wav-a} of the photoluminescent layer for the first light.
[Item 4] The light-emitting device according to any one of Items 1 to 3, wherein the first light has the maximum intensity in a first direction determined in advance by the submicron structure.
[Item 5] The light-emitting device according to Item 4, wherein the first direction is normal to the photoluminescent layer.
[Item 6] The light-emitting device according to Item 4 or 5, wherein the first light emitted in the first direction is linearly polarized light.
[Item 7] The light-emitting device according to any one of Items 4 to 6, wherein the directional angle of the first light with respect to the first direction is less than 15 degrees.
[Item 8] The light-emitting device according to any one of Items 4 to 7, wherein second light having a wavelength λ_{b} different from the wavelength λₐ of the first light has the maximum intensity in a second direction different from the first direction.
[Item 9] The light-emitting device according to any one of Items 1 to 8, wherein the light-transmissive layer has the submicron structure.
[Item 10] The light-emitting device according to any one of Items 1 to 9, wherein the photoluminescent layer has the submicron structure.
[Item 11] The light-emitting device according to any one of Items 1 to 8, wherein

the photoluminescent layer has a flat main surface, and

the light-transmissive layer is located on the flat main surface of the photoluminescent layer and has the submicron structure.

[Item 12] The light-emitting device according to Item 11, wherein the photoluminescent layer is supported by a transparent substrate.
[Item 13] The light-emitting device according to any one of Items 1 to 8, wherein

the light-transmissive layer is a transparent substrate having the submicron structure on a main surface thereof, and

the photoluminescent layer is located on the submicron structure.

[Item 14] The light-emitting device according to Item 1 or 2, wherein the refractive index nₜ₋ₐ of the light-transmissive layer for the first light is higher than or equal to the refractive index n_{wav-a} of the photoluminescent layer for the first light, and each of the projections or recesses in the submicron structure has a height or depth of 150 nm or less.
[Item 15] The light-emitting device according to any one of Items 1 and 3 to 14, wherein

the submicron structure includes at least one periodic structure having at least the projections or recesses, and the at least one periodic structure includes a first periodic structure having a period pₐ that satisfies λₐ/n_{wav-a}<pₐ<λₐ, and the first periodic structure is a one-dimensional periodic structure.

[Item 16] The light-emitting device according to Item 15, wherein light emitted from the photoluminescent layer includes second light having a wavelength λ_{b} different from the wavelength λₐ in air, the at least one periodic structure further includes a second periodic structure having a period p_{b} that satisfies λ_{b}/n_{wav-b}<p_{b}<λ_{b}, wherein n_{wav-b} denotes a refractive index of the photoluminescent layer for the second light, and

the second periodic structure is a one-dimensional periodic structure.

[Item 17] The light-emitting device according to any one of Items 1 and 3 to 14, wherein the submicron structure includes at least two periodic structures having at least the projections or recesses, and the at least two periodic structures include a two-dimensional periodic structure having periodicity in different directions.
[Item 18] The light-emitting device according to any one of Items 1 and 3 to 14, wherein

the submicron structure includes periodic structures having at least the projections or recesses, and

the periodic structures include periodic structures arranged in a matrix.

[Item 19] The light-emitting device according to any one of Items 1 and 3 to 14, wherein

the submicron structure includes periodic structures having at least the projections or recesses, and

the periodic structures include a periodic structure having a period pₑₓ that satisfies λₑₓ/n_{wav-ex}<pₑₓ<λₑₓ, wherein λₑₓ denotes the wavelength of excitation light in air for a photoluminescent material contained in the photoluminescent layer, and n_{wav-ex} denotes the refractive index of the photoluminescent layer for the excitation light.

[Item 20] A light-emitting device including

photoluminescent layers and light-transmissive layers,

wherein at least two of the photoluminescent layers are independently the photoluminescent layer according to any one of Items 1 to 19, and at least two of the light-transmissive layers are independently the light-transmissive layer according to any one of Items 1 to 19.

[Item 21] The light-emitting device according to Item 20, wherein the photoluminescent layers and the light-transmissive layers are stacked on top of each other.
[Item 22] A light-emitting device including

a photoluminescent layer,

a light-transmissive layer located on or near the photoluminescent layer, and

a submicron structure that is formed on at least one of the photoluminescent layer and the light-transmissive layer and that extends in a plane of the photoluminescent layer or the light-transmissive layer,

wherein light for forming a quasi-guided mode in the photoluminescent layer and the light-transmissive layer is emitted.

[Item 23] A light-emitting device including

a waveguide layer capable of guiding light, and

a periodic structure located on or near the waveguide layer,

wherein the waveguide layer contains a photoluminescent material, and

the waveguide layer includes a quasi-guided mode in which light emitted from the photoluminescent material is guided while interacting with the periodic structure.

[Item 24] A light-emitting device including

a photoluminescent layer,

a light-transmissive layer located on or near the photoluminescent layer, and

a submicron structure that is formed on at least one of the photoluminescent layer and the light-transmissive layer and that extends in a plane of the photoluminescent layer or the light-transmissive layer,

wherein the submicron structure has projections or recesses, and

the distance Dᵢₙₜ between adjacent projections or recesses, the wavelength λₑₓ of excitation light in air for a photoluminescent material contained in the photoluminescent layer, and the refractive index n_{wav-ex} of a medium having the highest refractive index for the excitation light out of media present in an optical path to the photoluminescent layer or the light-transmissive layer satisfy λₑₓ/n_{wav-ex}<Dᵢₙₜ<λₑₓ.

[Item 25] The light-emitting device according to Item 24, wherein the submicron structure includes at least one periodic structure having at least the projections or recesses, and the at least one periodic structure includes a first periodic structure having a period pₐₓ that satisfies λₑₓ/n_{wav-ex}<pₑₓ<λₑₓ.
[Item 26] A light-emitting device including

a light-transmissive layer,

a submicron structure that is formed in the light-transmissive layer and extends in a plane of the light-transmissive layer, and

a photoluminescent layer located on or near the submicron structure,

wherein the submicron structure has projections or recesses,

light emitted from the photoluminescent layer includes first light having a wavelength λₐ in air,

the submicron structure includes at least one periodic structure having at least the projections or recesses, and

the refractive index n_{wav-a} of the photoluminescent layer for the first light and the period pₐ of the at least one periodic structure satisfy λₐ/n_{wav-a}<pₐ<λₐ.

[Item 27] A light-emitting device including

a photoluminescent layer,

a light-transmissive layer having a higher refractive index than the photoluminescent layer, and

a submicron structure that is formed in the light-transmissive layer and extends in a plane of the light-transmissive layer,

wherein the submicron structure has projections or recesses,

light emitted from the photoluminescent layer includes first light having a wavelength λₐ in air, and

the submicron structure includes at least one periodic structure having at least the projections or recesses, and

the refractive index n_{wav-a} of the photoluminescent layer for the first light and the period pₐ of the at least one periodic structure satisfy λₐ/n_{wav-a}<pₐ<λₐ.

[Item 28] A light-emitting device including

a photoluminescent layer, and

a submicron structure that is formed in the photoluminescent layer and extends in a plane of the photoluminescent layer,

wherein the submicron structure has projections or recesses,

light emitted from the photoluminescent layer includes first light having a wavelength λₐ in air,

the submicron structure includes at least one periodic structure having at least the projections or recesses, and

the refractive index n_{wav-a} of the photoluminescent layer for the first light and the period pₐ of the at least one periodic structure satisfy λₐ/n_{wav-a}<pₐ<λₐ.

[Item 29] The light-emitting device according to any one of Items 1 to 21 and 24 to 28, wherein the submicron structure has both the projections and the recesses.
[Item 30] The light-emitting device according to any one of Items 1 to 22 and 24 to 27, wherein the photoluminescent layer is in contact with the light-transmissive layer.
[Item 31] The light-emitting device according to Item 23, wherein the waveguide layer is in contact with the periodic structure.
[Item 32] A light-emitting apparatus including

the light-emitting device according to any one of Items 1 to 31, and

an excitation light source for irradiating the photoluminescent layer with excitation light.

[Item 33] A light-emitting device including:

a photoluminescent layer that has a first surface perpendicular to a thickness direction thereof and emits light containing first light and second light, an area of the first surface being larger than a sectional area of the photoluminescent layer perpendicular to the first surface; and

a light-transmissive layer located on the photoluminescent layer, wherein

at least one of the photoluminescent layer and the light-transmissive layer has a submicron structure including at least two periodic structures having at least projections or recesses arranged perpendicular to the thickness direction of the photoluminescent layer,

at least one of the photoluminescent layer and the light-transmissive layer has a light emitting surface perpendicular to the thickness direction of the photoluminescent layer, the first light and the second light being emitted from the light emitting surface,

the first light has a wavelength λₐ in air,

the second light has a wavelength λ_{b} in air,

the at least two periodic structures include a first periodic structure having a first period pₐ that satisfies λₐ/n_{wav-a}<pₐ<λₐ and a second periodic structure having a second period p_{b} that satisfies λ_{b}/n_{wav-b}<p_{b}<λ_{b}, where n_{wav-a} and n_{wav-b} denote refractive indices of the photoluminescent layer for the first light and the second light, respectively, and

a thickness of the photoluminescent layer, the refractive indexes n_{wav-a} and n_{wav-b}, and the first and second periods pₐ and p_{b} are set to limit directional angles of the first and second light emitted from the light emitting surface.
[Item 34] The light-emitting device according to Item 1, wherein the wavelength λₐ of the first light is equal to the wavelength λ_{b} of the second light, the first period pₐ is equal to the second period p_{b}, and the first periodic structure has a different direction of periodicity from the second periodic structure.
[Item 35] The light-emitting device according to Item 33, wherein the first period pₐ is different from the second period p_{b}, and the first periodic structure and the second periodic structure have the same direction of periodicity.
[Item 36] The light-emitting device according to any one of Items 33 to 35, wherein the first periodic structure and the second periodic structure are located on the same surface of the at least one of the photoluminescent layer and the light-transmissive layer.
[Item 37] The light-emitting device according to any one of Items 33 to 35, wherein one of the first periodic structure and the second periodic structure is located on a top surface of the photoluminescent layer, and the other is located on a bottom surface of the photoluminescent layer.
[Item 38] The light-emitting device according to any one of Items 33 to 35, further including

an additional photoluminescent layer in contact with a bottom surface of the photoluminescent layer,

wherein one of the first periodic structure and the second periodic structure is located on a top surface of the photoluminescent layer, and the other is located on a bottom surface of the additional photoluminescent layer.

[Item 39] The light-emitting device according to any one of Items 33 to 35, further including

an additional photoluminescent layer in contact with a bottom surface of the photoluminescent layer,

wherein one of the first periodic structure and the second periodic structure is located on a top surface of the photoluminescent layer, and the other is located on a top surface of the additional photoluminescent layer.

[Item 40] The light-emitting device according to any one of Items 33 to 35, further including

a substrate for supporting the photoluminescent layer; and an additional photoluminescent layer on a bottom surface of the substrate,

wherein one of the first periodic structure and the second periodic structure is located on a top surface of the substrate, and the other is located on the bottom surface of the substrate.

[Item 41] A light-emitting device including:

a photoluminescent layer that has a first surface perpendicular to a thickness direction thereof and emits light containing first light and second light, an area of the first surface being larger than a sectional area of the photoluminescent layer perpendicular to the first surface; and

a light-transmissive layer located on the photoluminescent layer, wherein

at least one of the photoluminescent layer and the light-transmissive layer has a submicron structure having projections or recesses arranged perpendicular to the thickness direction of the photoluminescent layer,

at least one of the photoluminescent layer and the light-transmissive layer has a light emitting surface perpendicular to the thickness direction of the photoluminescent layer, the first light and the second light being emitted from the light emitting surface,

a distribution of spatial frequency intensity obtained by Fourier transformation of a two-dimensional pattern of height of the projections or the recesses includes at least two pairs of two points located at point-symmetrical positions with respect to a central point,

the at least two pairs include a pair of two points at a distance of 1/pₐ from the central point and another pair of two points at a distance of 1/p_{b} from the central point,

the first light has a wavelength λₐ in air and the second light has a wavelength λ_{b} in air,

the photoluminescent layer has refractive indices n_{wav-a} and n_{wav-b} for the first light and the second light, respectively, that satisfy λₐ/n_{wav-a}<pₐ<λₐ and λ_{b}/n_{wav-b}<p_{b}<λ_{b}, and

a thickness of the photoluminescent layer, the refractive indexes n_{wav-a} and n_{wav-b}, and the first and second periods pₐ and p_{b} are set to limit directional angles of the first and second light emitted from the light emitting surface.

[Item 42] The light-emitting device according to Item 41, wherein the at least two pairs include two pairs having the same distance from the central point.
[Item 43] The light-emitting device according to Item 41 or 42, wherein the at least two pairs include two pairs having different distances from the central point.
[Item 44] The light-emitting device according to any one of Items 41 to 43, wherein the submicron structure is located on the same surface of the at least one of the photoluminescent layer and the light-transmissive layer.
[Item 45] A light-emitting device including:

a light-transmissive layer having a submicron structure; and

a photoluminescent layer that is located on the submicron structure, has a first surface perpendicular to a thickness direction thereof, and emits light containing first light and second light, an area of the first surface being larger than a sectional area of the photoluminescent layer perpendicular to the first surface, wherein

the submicron structure includes at least two periodic structures having at least projections or recesses arranged perpendicular to the thickness direction of the photoluminescent layer,

at least one of the photoluminescent layer and the light-transmissive layer has a light emitting surface perpendicular to the thickness direction of the photoluminescent layer, the first light and the second light being emitted from the light emitting surface,

the first light has a wavelength λₐ in air,

the second light has a wavelength λ_{b} in air,

the at least two periodic structures include a first periodic structure having a first period pₐ that satisfies λₐ/n_{wav-a}<pₐ<λₐ and a second periodic structure having a second period p_{b} that satisfies λ_{b}/n_{wav-b}<p_{b}<λ_{b}, where n_{wav-a} and n_{wav-b} denote refractive indices of the photoluminescent layer for the first light and the second light, respectively, and

a thickness of the photoluminescent layer, the refractive indexes n_{wav-a} and n_{wav-b}, and the first and second periods pₐ and p_{b} are set to limit directional angles of the first and second light emitted from the light emitting surface.
[Item 46] A light-emitting device including:

a photoluminescent layer that has a first surface perpendicular to a thickness direction thereof and emits light containing first light and second light, an area of the first surface being larger than a sectional area of the photoluminescent layer perpendicular to the first surface; and

a light-transmissive layer having a higher refractive index than the photoluminescent layer, wherein

the light-transmissive layer has a submicron structure including at least two periodic structures having at least projections or recesses arranged perpendicular to the thickness direction of the photoluminescent layer,

at least one of the photoluminescent layer and the light-transmissive layer has a light emitting surface perpendicular to the thickness direction of the photoluminescent layer, the first light and the second light being emitted from the light emitting surface,

the first light has a wavelength λₐ in air,

the second light has a wavelength λ_{b} in air,

the at least two periodic structures include a first periodic structure having a first period pₐ that satisfies λₐ/n_{wav-a}<pₐ<λₐ and a second periodic structure having a second period p_{b} that satisfies λ_{b}/n_{wav-b}<p_{b}<λ_{b}, where n_{wav-a} and n_{wav-b} denote refractive indices of the photoluminescent layer for the first light and the second light, respectively, and

a thickness of the photoluminescent layer, the refractive indexes n_{wav-a} and n_{wav-b}, and the first and second periods pₐ and p_{b} are set to limit directional angles of the first and second light emitted from the light emitting surface.
[Item 47] The light-emitting device according to any one of Items 33 to 46, wherein the photoluminescent layer is in contact with the light-transmissive layer.
[Item 48] A light-emitting device including:

a photoluminescent layer that has a first surface perpendicular to a thickness direction thereof and emits light containing first light and second light, an area of the first surface being larger than a sectional area of the photoluminescent layer perpendicular to the first surface, wherein

the photoluminescent layer has a submicron structure including at least two periodic structures having at least projections or recesses arranged perpendicular to the thickness direction of the photoluminescent layer,

the photoluminescent layer has a light emitting surface perpendicular to the thickness direction of the photoluminescent layer, the first light being emitted from the light emitting surface,

the first light has a wavelength λₐ in air,

the second light has a wavelength λ_{b} in air,

the at least two periodic structures include a first periodic structure having a first period pₐ that satisfies λₐ/n_{wav-a}<pₐ<λₐ and a second periodic structure having a second period p_{b} that satisfies λ_{b}/n_{wav-b}<p_{b}<λ_{b}, where n_{wav-a} and n_{wav-b} denote refractive indices of the photoluminescent layer for the first light and the second light, respectively, and

a thickness of the photoluminescent layer, the refractive indexes n_{wav-a} and n_{wav-b}, and the first and second periods pₐ and p_{b} are set to limit directional angles of the first and second light emitted from the light emitting surface.
[Item 49] The light-emitting device according to any one of Items 33 to 48, wherein the submicron structure has both the projections and the recesses.
[Item 50] The light-emitting device according to any one of Items 33 to 49, wherein the photoluminescent layer includes a phosphor.
[Item 51] The light-emitting device according to any one of Items 33 to 50, wherein 380 nm≦λₐ≦780 nm and 380 nm≦λ_{b}≦780 nm are satisfied.
[Item 52] The light-emitting device according to any one of Items 33 to 51, wherein the thickness of the photoluminescent layer, the refractive indexes n_{wav-a} and n_{wav-b}, and the first and second periods pₐ and p_{b} are set to allow an electric field to be formed in the photoluminescent layer, in which antinodes of the electric field are located in areas, the areas each corresponding to respective one of the projections and/or recesses.
[Item 53] The light-emitting device according to any one of Items 33 to 52, wherein the light-transmissive layer is located indirectly on the photoluminescent layer.
[Item 54] The light-emitting device according to any one of Items 33 to 53, wherein the thickness of the photoluminescent layer, the refractive indexes n_{wav-a} and n_{wav-b}, and the first and second periods pₐ and p_{b} are set to allow an electric field to be formed in the photoluminescent layer, in which antinodes of the electric field are located at, or adjacent to, at least the projections or recesses.
[Item 55] The light-emitting device according to any one of Items 33 to 54, further comprising a substrate that has a refractive index nₛ₋ₐ for the first light and a refractive index n_{s-b} for the second light is located on the photoluminescent layer, wherein λₐ/n_{wav-a}<pₐ<λₐ/nₛ₋ₐ and λ_{b}/n_{wav-b}<p_{b}<λ_{b}/n_{s-b} are satisfied.
[Item 56] A light-emitting apparatus including

the light-emitting device according to any one of Items 33 to 55, and

an excitation light source for irradiating the photoluminescent layer with excitation light.

A light-emitting device according to an embodiment of the present disclosure includes a photoluminescent layer, a light-transmissive layer located on or near the photoluminescent layer, and a submicron structure that is formed on at least one of the photoluminescent layer and the light-transmissive layer and that extends in a plane of the photoluminescent layer or the light-transmissive layer. The submicron structure has projections or recesses, light emitted from the photoluminescent layer includes first light having a wavelength λₐ in air, and the distance Dᵢₙₜ between adjacent projections or recesses and the refractive index n_{wav-a} of the photoluminescent layer for the first light satisfy λₐ/n_{wav-a}<Dᵢₙₜ<λₐ. The wavelength λₐ is, for example, within the visible wavelength range (for example, 380 to 780 nm).

The photoluminescent layer contains a photoluminescent material. The term “photoluminescent material” refers to a material that emits light in response to excitation light. The term “photoluminescent material” encompasses fluorescent materials and phosphorescent materials in a narrow sense, encompasses inorganic materials and organic materials (for example, dyes), and encompasses quantum dots (that is, tiny semiconductor particles). The photoluminescent layer may contain a matrix material (host material) in addition to the photoluminescent material. Examples of matrix materials include resins and inorganic materials such as glasses and oxides.

The light-transmissive layer located on or near the photoluminescent layer is made of a material with high transmittance to the light emitted from the photoluminescent layer, for example, inorganic materials or resins. For example, the light-transmissive layer is desirably formed of a dielectric material (particularly, an insulator having low light absorptivity). For example, the light-transmissive layer may be a substrate that supports the photoluminescent layer. If the surface of the photoluminescent layer facing air has the submicron structure, the air layer can serve as the light-transmissive layer.

In a light-emitting device according to an embodiment of the present disclosure, a submicron structure (for example, a periodic structure) on at least one of the photoluminescent layer and the light-transmissive layer forms a unique electric field distribution inside the photoluminescent layer and the light-transmissive layer, as described in detail later with reference to the results of calculations and experiments. This electric field distribution is formed by an interaction between guided light and the submicron structure and may also be referred to as a “quasi-guided mode”.

The quasi-guided mode can be utilized to improve the luminous efficiency, directionality, and polarization selectivity of photoluminescence, as described later. The term “quasi-guided mode” may be used in the following description to describe novel structures and/or mechanisms contemplated by the inventors. However, such a description is for illustrative purposes only and is not intended to limit the present disclosure in any way.

For example, the submicron structure has projections, and the distance (the center-to-center distance) Dᵢₙₜ between adjacent projections satisfies λₐ/n_{wav-a}<Dᵢₙₜ<λₐ. Instead of the projections, the submicron structure may have recesses. For simplicity, the following description will be directed to a submicron structure having projections. The symbol λ denotes the wavelength of light, and the symbol λₐ denotes the wavelength of light in air. The symbol n_{wav} denotes the refractive index of the photoluminescent layer. If the photoluminescent layer is a medium containing materials, the refractive index n_{wav} denotes the average refractive index of the materials weighted by their respective volume fractions.

Although it is desirable to use the symbol n_{wav-a} to refer to the refractive index for light having a wavelength λₐ because the refractive index n generally depends on the wavelength, it may be abbreviated for simplicity. The symbol n_{wav} basically denotes the refractive index of the photoluminescent layer; however, if a layer having a higher refractive index than the photoluminescent layer is adjacent to the photoluminescent layer, the refractive index n_{wav} denotes the average refractive index of the layer having a higher refractive index and the photoluminescent layer weighted by their respective volume fractions. This is optically equivalent to a photoluminescent layer composed of layers of different materials.

The effective refractive index n_{eff} of the medium for light in the quasi-guided mode satisfies nₐ<n_{eff}<n_{wav}, wherein nₐ denotes the refractive index of air. If light in the quasi-guided mode is assumed to be light propagating through the photoluminescent layer while being totally reflected at an angle of incidence θ, the effective refractive index n_{eff} can be written as n_{eff}=n_{wav} sin θ. The effective refractive index n_{eff} is determined by the refractive index of the medium present in the region where the electric field of the quasi-guided mode is distributed.

For example, if the submicron structure is formed in the light-transmissive layer, the effective refractive index n_{eff} depends not only on the refractive index of the photoluminescent layer but also on the refractive index of the light-transmissive layer. Because the electric field distribution also varies depending on the polarization direction of the quasi-guided mode (that is, the TE mode or the TM mode), the effective refractive index n_{eff} can differ between the TE mode and the TM mode.

The submicron structure is formed on at least one of the photoluminescent layer and the light-transmissive layer. If the photoluminescent layer and the light-transmissive layer are in contact with each other, the submicron structure may be formed on the interface between the photoluminescent layer and the light-transmissive layer. In such a case, the photoluminescent layer and the light-transmissive layer have the submicron structure. The photoluminescent layer may have no submicron structure. In such a case, a light-transmissive layer having a submicron structure is located on or near the photoluminescent layer. A phrase like “a light-transmissive layer (or its submicron structure) located on or near the photoluminescent layer”, as used herein, typically means that the distance between these layers is less than half the wavelength λₐ.

This allows the electric field of a guided mode to reach the submicron structure, thus forming a quasi-guided mode. However, the distance between the submicron structure of the light-transmissive layer and the photoluminescent layer may exceed half the wavelength λₐ if the light-transmissive layer has a higher refractive index than the photoluminescent layer. If the light-transmissive layer has a higher refractive index than the photoluminescent layer, light reaches the light-transmissive layer even if the above relationship is not satisfied. In the present specification, if the photoluminescent layer and the light-transmissive layer have a positional relationship that allows the electric field of a guided mode to reach the submicron structure and form a quasi-guided mode, they may be associated with each other.

The submicron structure, which satisfies λₐ/n_{wav-a}<Dᵢₙₜ<λₐ, as described above, is characterized by a submicron size. The submicron structure includes at least one periodic structure, as in the light-emitting devices according to the embodiments described in detail later. The at least one periodic structure has a period pₐ that satisfies λₐ/n_{wav-a}<pₐ<λₐ. Thus, the submicron structure includes a periodic structure in which the distance Dᵢₙₜ between adjacent projections is constant at pₐ. If the submicron structure includes a periodic structure, light in the quasi-guided mode propagates while repeatedly interacting with the periodic structure so that the light is diffracted by the submicron structure. Unlike the phenomenon in which light propagating through free space is diffracted by a periodic structure, this is the phenomenon in which light is guided (that is, repeatedly totally reflected) while interacting with the periodic structure. This can efficiently diffract light even if the periodic structure causes a small phase shift (that is, even if the periodic structure has a small height).

The above mechanism can be utilized to improve the luminous efficiency of photoluminescence by the enhancement of the electric field due to the quasi-guided mode and also to couple the emitted light into the quasi-guided mode. The angle of travel of the light in the quasi-guided mode is varied by the angle of diffraction determined by the periodic structure. This can be utilized to output light of a particular wavelength in a particular direction (that is, significantly improve the directionality). Furthermore, high polarization selectivity can be simultaneously achieved because the effective refractive index n_{eff} (=n_{wav} sin θ) differs between the TE mode and the TM mode. For example, as demonstrated by the experimental examples below, a light-emitting device can be provided that outputs intense linearly polarized light (for example, the TM mode) of a particular wavelength (for example, 610 nm) in the front direction. The directional angle of the light output in the front direction is, for example, less than 15 degrees. The term “directional angle” refers to the angle of one side with respect to the front direction, which is assumed to be 0 degrees.

Conversely, a submicron structure having a lower periodicity results in a lower directionality, luminous efficiency, polarization, and wavelength selectivity. The periodicity of the submicron structure may be adjusted depending on the need. The periodic structure may be a one-dimensional periodic structure, which has a higher polarization selectivity, or a two-dimensional periodic structure, which allows for a lower polarization.

The submicron structure may include periodic structures. For example, these periodic structures may have different periods or different periodic directions (axes). The periodic structures may be formed on the same plane or may be stacked on top of each other. The light-emitting device may include photoluminescent layers and light-transmissive layers, and each of the layers may have submicron structures.

The submicron structure can be used not only to control the light emitted from the photoluminescent layer but also to efficiently guide excitation light into the photoluminescent layer. That is, the excitation light can be diffracted and coupled into the quasi-guided mode to guide light in the photoluminescent layer and the light-transmissive layer by the submicron structure to efficiently excite the photoluminescent layer. A submicron structure may be used that satisfies λₑₓ/n_{wav-ex}<Dᵢₙₜ<λₑₓ, wherein λₑₓ denotes the wavelength in air of the light that excites the photoluminescent material, and n_{wav-ex} denotes the refractive index of the photoluminescent layer for the excitation light. The symbol n_{wav-ex} denotes the refractive index of the photoluminescent layer for the emission wavelength of the photoluminescent material. Alternatively, a submicron structure may be used that includes a periodic structure having a period pₑₓ that satisfies λₑₓ/n_{wav-ex}<pₑₓ<λₑₓ. The excitation light has a wavelength λₑₓ of 450 nm, for example, but may have a shorter wavelength than visible light. If the excitation light has a wavelength within the visible range, it may be output together with the light emitted from the photoluminescent layer.

### 1. Underlying Knowledge Forming Basis of the Present Disclosure

The underlying knowledge forming the basis for the present disclosure will be described before describing specific embodiments of the present disclosure. As described above, photoluminescent materials such as those used for fluorescent lamps and white LEDs emit light in all directions and thus require optical elements such as reflectors and lenses to emit light in a particular direction. These optical elements, however, can be eliminated (or the size thereof can be reduced) if the photoluminescent layer itself emits directional light. This results in a significant reduction in the size of optical devices and equipment. With this idea in mind, the inventors have conducted a detailed study on the photoluminescent layer to achieve directional light emission.

The inventors have investigated the possibility of inducing light emission with particular directionality so that the light emitted from the photoluminescent layer is localized in a particular direction. Based on Fermi's golden rule, the emission rate Γ, which is a measure characterizing light emission, is represented by the equation (1):

$$Γ ( r ) = \frac{2 π}{ℏ} {〈 ( d \cdot E ( r ) ) 〉}^{2} ρ ( λ ) \qquad ( 1 )$$

In the equation (1), r is the vector indicating the position, λ is the wavelength of light, d is the dipole vector, E is the electric field vector, and ρ is the density of states. For many substances other than some crystalline substances, the dipole vector d is randomly oriented. The magnitude of the electric field E is substantially constant irrespective of the direction if the size and thickness of the photoluminescent layer are sufficiently larger than the wavelength of light. Hence, in most cases, the value of <(d·E(r))>² does not depend on the direction. Accordingly, the emission rate Γ is constant irrespective of the direction. Thus, in most cases, the photoluminescent layer emits light in all directions.

As can be seen from the equation (1), to achieve anisotropic light emission, it is necessary to align the dipole vector d in a particular direction or to enhance the component of the electric field vector in a particular direction. One of these approaches can be employed to achieve directional light emission. In the present disclosure, the results of a detailed study and analysis on structures for utilizing a quasi-guided mode in which the electric field component in a particular direction is enhanced by the confinement of light in the photoluminescent layer will be described below.

### 2. Structure for Enhancing Electric Field Only in Particular Direction

The inventors have investigated the possibility of controlling light emission using a guided mode with an intense electric field. Light can be coupled into a guided mode using a waveguide structure that itself contains a photoluminescent material. However, a waveguide structure simply formed using a photoluminescent material outputs little or no light in the front direction because the emitted light is coupled into a guided mode. Accordingly, the inventors have investigated the possibility of combining a waveguide containing a photoluminescent material with a periodic structure (including projections or recesses or both). When the electric field of light is guided in a waveguide while overlapping with a periodic structure located on or near the waveguide, a quasi-guided mode is formed by the effect of the periodic structure. That is, the quasi-guided mode is a guided mode restricted by the periodic structure and is characterized in that the antinodes of the amplitude of the electric field have the same period as the periodic structure. Light in this mode is confined in the waveguide structure to enhance the electric field in a particular direction. This mode also interacts with the periodic structure to undergo diffraction so that the light in this mode is converted into light propagating in a particular direction and can thus be output from the waveguide. The electric field of light other than the quasi-guided mode is not enhanced because little or no such light is confined in the waveguide. Thus, most light is coupled into a quasi-guided mode with a large electric field component.

That is, the inventors have investigated the possibility of using a photoluminescent layer containing a photoluminescent material as a waveguide (or a waveguide layer including a photoluminescent layer) in combination with a periodic structure located on or near the waveguide to couple light into a quasi-guided mode in which the light is converted into light propagating in a particular direction, thereby providing a directional light source.

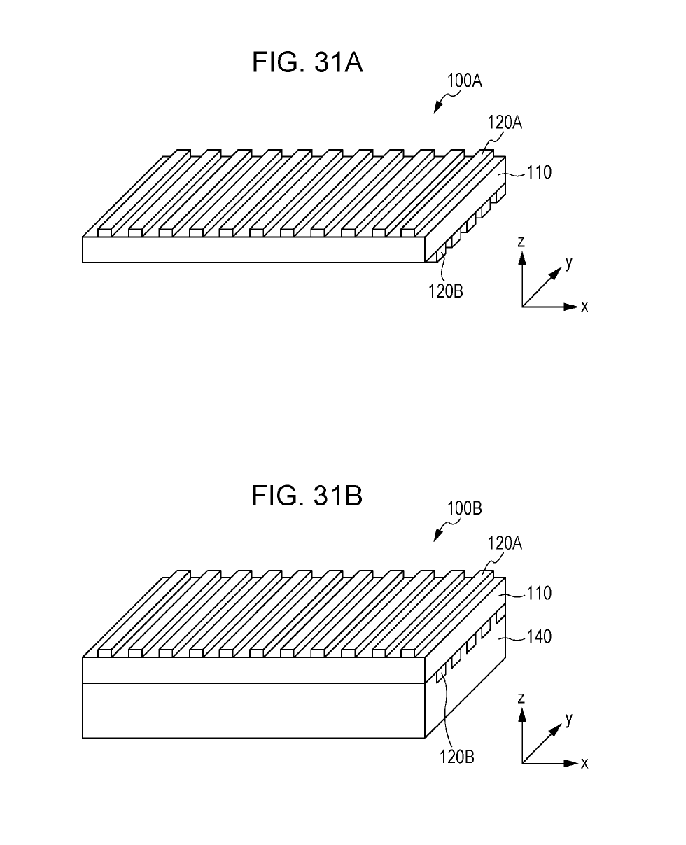

As a simple waveguide structure, the inventors have studied slab waveguides. A slab waveguide has a planar structure in which light is guided. FIG. 30 is a schematic perspective view of a slab waveguide 110S. There is a mode of light propagating through the waveguide 110S if the waveguide 110S has a higher refractive index than a transparent substrate 140 that supports the waveguide 110S. If such a slab waveguide includes a photoluminescent layer, the electric field of light emitted from an emission point overlaps largely with the electric field of a guided mode. This allows most of the light emitted from the photoluminescent layer to be coupled into the guided mode. If the photoluminescent layer has a thickness close to the wavelength of the light, a situation can be created where there is only a guided mode with a large electric field amplitude.

If a periodic structure is located on or near the photoluminescent layer, the electric field of the guided mode interacts with the periodic structure to form a quasi-guided mode. Even if the photoluminescent layer is composed of a plurality of layers, a quasi-guided mode is formed as long as the electric field of the guided mode reaches the periodic structure. Not all parts of the photoluminescent layer needs to be formed of a photoluminescent material, provided that at least a portion of the photoluminescent layer functions to emit light.

If the periodic structure is made of a metal, a mode due to the guided mode and plasmon resonance is formed. This mode has different properties from the quasi-guided mode. This mode is less effective in enhancing emission because a large loss occurs due to high absorption by the metal. Thus, it is desirable to form the periodic structure using a dielectric material having low absorptivity.

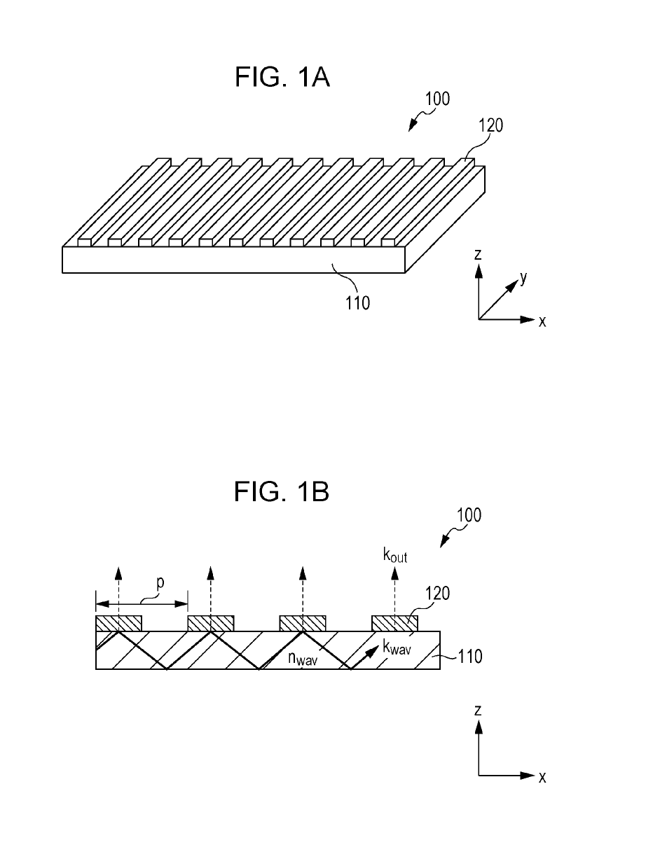

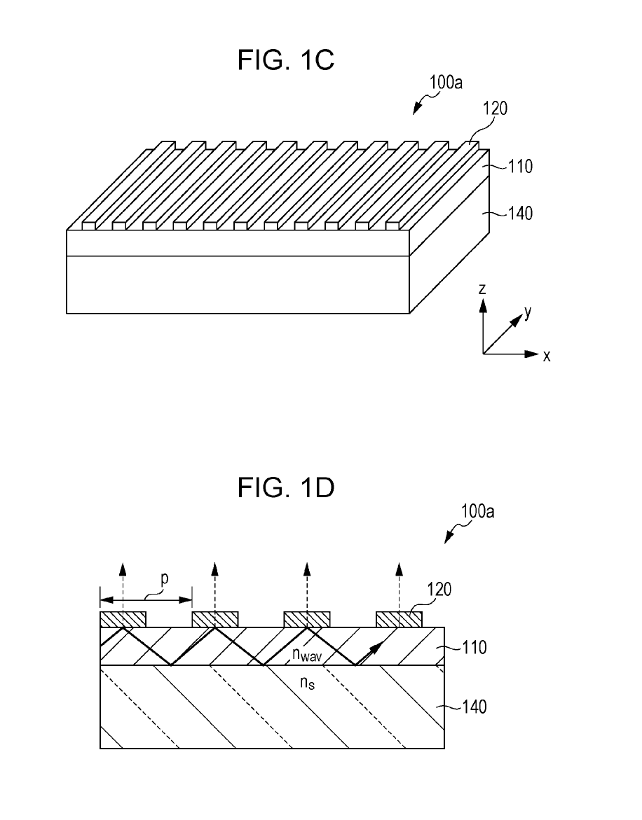

The inventors have studied the coupling of light into a quasi-guided mode that can be output as light propagating in a particular angular direction using a periodic structure formed on a waveguide (for example, a photoluminescent layer). FIG. 1A is a schematic perspective view of a light-emitting device 100 including a waveguide (for example, a photoluminescent layer) 110 and a periodic structure (for example, a light-transmissive layer) 120. The light-transmissive layer 120 is hereinafter also referred to as a periodic structure 120 if the light-transmissive layer 120 forms a periodic structure (that is, if a periodic submicron structure is formed on the light-transmissive layer 120). In this example, the periodic structure 120 is a one-dimensional periodic structure in which stripe-shaped projections extending in the y direction are arranged at regular intervals in the x direction. FIG. 1B is a cross-sectional view of the light-emitting device 100 taken along a plane parallel to the xz plane. If a periodic structure 120 having a period p is provided in contact with the waveguide 110, a quasi-guided mode having a wave number k_{wav} in the in-plane direction is converted into light propagating outside the waveguide 110. The wave number kₒᵤₜ of the light can be represented by the equation (2):

$${k}_{out} = {k}_{wav} - m \frac{2 π}{p} \qquad ( 2 )$$

wherein m is an integer indicating the diffraction order.

For simplicity, the light guided in the waveguide 110 is assumed to be a ray of light propagating at an angle θ_{wav}. This approximation gives the equations (3) and (4):

$$\begin{matrix}\frac{{k}_{wav} {λ}_{0}}{2 π} = {n}_{wav} sin {θ}_{wav} & ( 3 ) \\ \frac{{k}_{out} {λ}_{0}}{2 π} = {n}_{out} sin {θ}_{out} & ( 4 )\end{matrix}$$

In these equations, λ₀ denotes the wavelength of the light in air, n_{wav} denotes the refractive index of the waveguide 110, nₒᵤₜ denotes the refractive index of the medium on the light output side, and θₒᵤₜ denotes the angle at which the light is output from the waveguide 110 to a substrate or air. From the equations (2) to (4), the output angle θₒᵤₜ can be represented by the equation (5):

nₒᵤₜ sin θₒᵤₜ=n_{wav} sin θ_{wav}−mλ₀/p (5)

If n_{wav} sin θ_{wav}=mλ₀/p in the equation (5), this results in θₒᵤₜ=0, meaning that the light can be emitted in the direction perpendicular to the plane of the waveguide 110 (that is, in the front direction).

Based on this principle, light can be coupled into a particular quasi-guided mode and be converted into light having a particular output angle using the periodic structure to output intense light in that direction.

There are some constraints to achieving the above situation. To form a quasi-guided mode, the light propagating through the waveguide 110 has to be totally reflected. The conditions therefor are represented by the inequality (6):

nₒᵤₜ<n_{wav} sin θ_{wav} (6)

To diffract the quasi-guided mode using the periodic structure and thereby output the light from the waveguide 110, −1<sin θₒᵤₜ<1 has to be satisfied in the equation (5). Hence, the inequality (7) has to be satisfied:

$$- 1 < \frac{{n}_{wav}}{{n}_{out}} sin {θ}_{wav} - \frac{m {λ}_{0}}{{n}_{out} p} < 1 \qquad ( 7 )$$

Taking into account the inequality (6), the inequality (8) may be satisfied:

$$\frac{m {λ}_{0}}{2 {n}_{out}} < p \qquad ( 8 )$$

To output the light from the waveguide 110 in the front direction (θₒᵤₜ=0), as can be seen from the equation (5), the equation (9) has to be satisfied:

p=mλ₀/(n_{wav} sin θ_{wav}) (9)

As can be seen from the equation (9) and the inequality (6), the required conditions are represented by the inequality (10):

$$\frac{m {λ}_{0}}{{n}_{wav}} < p < \frac{m {λ}_{0}}{{n}_{out}} \qquad ( 10 )$$

If the periodic structure 120 as illustrated in FIGS. 1A and 1B is provided, it may be designed based on first-order diffracted light (that is, m=1) because higher-order diffracted light having m of 2 or more has low diffraction efficiency. In this embodiment, the period p of the periodic structure 120 is determined so as to satisfy the inequality (11), which is given by substituting m=1 into the inequality (10):

$$\frac{{λ}_{0}}{{n}_{wav}} < p < \frac{{λ}_{0}}{{n}_{out}} \qquad ( 11 )$$

If the waveguide (photoluminescent layer) 110 is not in contact with a transparent substrate, as illustrated in FIGS. 1A and 1B, nₒᵤₜ is equal to the refractive index of air (approximately 1.0). Thus, the period p may be determined so as to satisfy the inequality (12):

$$\frac{{λ}_{0}}{{n}_{wav}} < p < {λ}_{0} \qquad ( 12 )$$

Alternatively, a structure as illustrated in FIGS. 1C and 1D may be employed in which the photoluminescent layer 110 and the periodic structure 120 are formed on a transparent substrate 140. The refractive index nₛ of the transparent substrate 140 is higher than the refractive index of air. Thus, the period p may be determined so as to satisfy the inequality (13), which is given by substituting θₒᵤₜ=nₛ into the inequality (11):

$$\frac{{λ}_{0}}{{n}_{wav}} < p < \frac{{λ}_{0}}{{n}_{s}} \qquad ( 13 )$$

Although m=1 is assumed in the inequality (10) to give the inequalities (12) and (13), m≧2 may be assumed. That is, if both surfaces of the light-emitting device 100 are in contact with air layers, as shown in FIGS. 1A and 1B, the period p may be determined so as to satisfy the inequality (14):

$$\frac{m {λ}_{0}}{{n}_{wav}} < p < m {λ}_{0} \qquad ( 14 )$$

wherein m is an integer of 1 or more.

Similarly, if the photoluminescent layer 110 is formed on the transparent substrate 140, as in the light-emitting device 100a illustrated in FIGS. 1C and 1D, the period p may be determined so as to satisfy the inequality (15):

$$\frac{m {λ}_{0}}{{n}_{wav}} < p < \frac{m {λ}_{0}}{{n}_{s}} \qquad ( 15 )$$

By determining the period p of the periodic structure so as to satisfy the above inequalities, the light emitted from the photoluminescent layer 110 can be output in the front direction, thus providing a directional light-emitting device.

### 3. Verification by Calculations

### 3-1. Period and Wavelength Dependence

The inventors verified, by optical analysis, whether the output of light in a particular direction as described above is actually possible. The optical analysis was performed by calculations using DiffractMOD available from Cybernet Systems Co., Ltd. In these calculations, the change in the absorption of external light incident perpendicular to a light-emitting device by a photoluminescent layer was calculated to determine the enhancement of light output perpendicular to the light-emitting device. The calculation of the process by which external incident light is coupled into a quasi-guided mode and is absorbed by the photoluminescent layer corresponds to the calculation of a process opposite to the process by which light emitted from the photoluminescent layer is coupled into a quasi-guided mode and is converted into propagating light output perpendicular to the light-emitting device. Similarly, the electric field distribution of a quasi-guided mode was calculated from the electric field of external incident light.

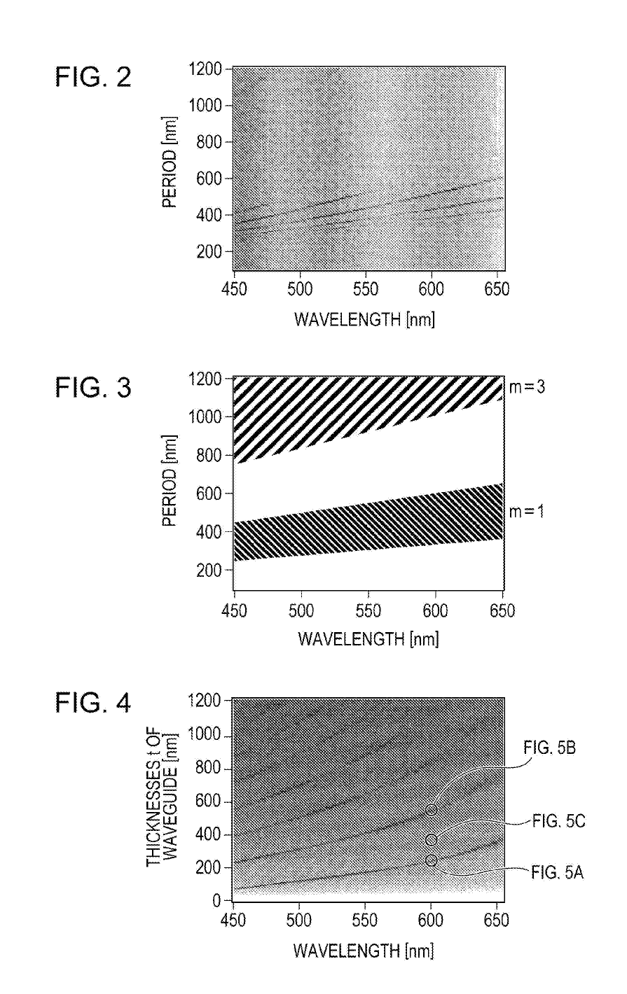

FIG. 2 shows the calculation results of the enhancement of light output in the front direction with varying emission wavelengths and varying periods of the periodic structure, where the photoluminescent layer was assumed to have a thickness of 1 μm and a refractive index n_{wav} of 1.8, and the periodic structure was assumed to have a height of 50 nm and a refractive index of 1.5. In these calculations, the periodic structure was assumed to be a one-dimensional periodic structure uniform in the y direction, as shown in FIG. 1A, and the polarization of the light was assumed to be the TM mode, which has an electric field component parallel to the y direction. The results in FIG. 2 show that there are enhancement peaks at certain combinations of wavelength and period. In FIG. 2, the magnitude of the enhancement is expressed by different shades of color; a darker color (black) indicates a higher enhancement, whereas a lighter color (white) indicates a lower enhancement.

In the above calculations, the periodic structure was assumed to have a rectangular cross section as shown in FIG. 1B. FIG. 3 is a graph illustrating the conditions for m=1 and m=3 in the inequality (10). A comparison between FIGS. 2 and 3 shows that the peaks in FIG. 2 are located within the regions corresponding to m=1 and m=3. The intensity is higher for m=1 because first-order diffracted light has a higher diffraction efficiency than third- or higher-order diffracted light. There is no peak for m=2 because of low diffraction efficiency in the periodic structure.

In FIG. 2, a plurality of lines are observed in each of the regions corresponding to m=1 and m=3 in FIG. 3. This indicates the presence of a plurality of quasi-guided modes.

### 3-2. Thickness Dependence

FIG. 4 is a graph showing the calculation results of the enhancement of light output in the front direction with varying emission wavelengths and varying thicknesses t of the photoluminescent layer, where the photoluminescent layer was assumed to have a refractive index n_{wav} of 1.8, and the periodic structure was assumed to have a period of 400 nm, a height of 50 nm, and a refractive index of 1.5. FIG. 4 shows that the enhancement of the light peaks at a particular thickness t of the photoluminescent layer.

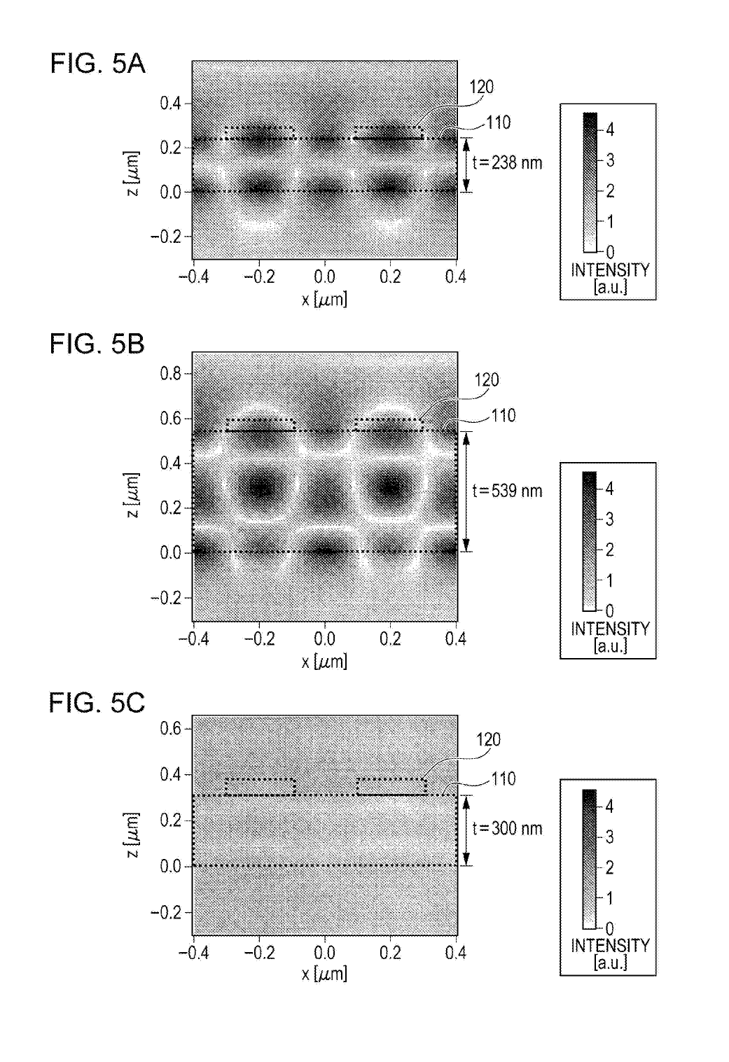

FIGS. 5A and 5B show the calculation results of the electric field distributions of a mode to guide light in the x direction for a wavelength of 600 nm and thicknesses t of 238 nm and 539 nm, respectively, at which there are peaks in FIG. 4. For comparison, FIG. 5C shows the results of similar calculations for a thickness t of 300 nm, at which there is no peak. In these calculations, as in the above calculations, the periodic structure was a one-dimensional periodic structure uniform in the y direction. In each figure, a black region indicates a higher electric field intensity, whereas a white region indicates a lower electric field intensity. Whereas the results for t=238 nm and t=539 nm show high electric field intensity, the results for t=300 nm shows low electric field intensity as a whole. This is because there are guided modes for t=238 nm and t=539 nm so that light is strongly confined. Furthermore, regions with the highest electric field intensity (that is, antinodes) are necessarily present in or directly below the projections, indicating the correlation between the electric field and the periodic structure 120. Thus, the resulting guided mode depends on the arrangement of the periodic structure 120. A comparison between the results for t=238 nm and t=539 nm shows that these modes differ in the number of nodes (white regions) of the electric field in the z direction by one.

### 3-3. Polarization Dependence

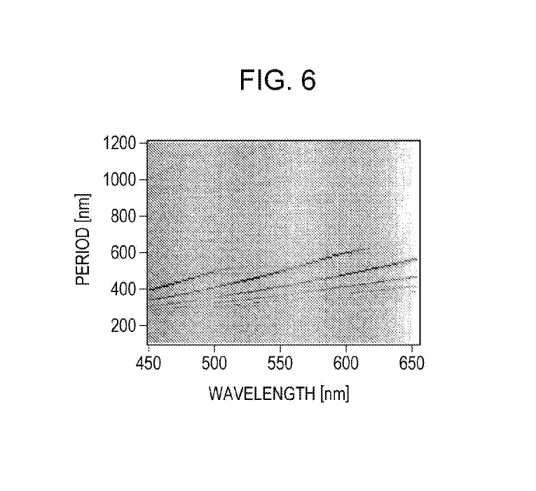

To examine the polarization dependence, the enhancement of light was calculated under the same conditions as in FIG. 2 except that the polarization of the light was assumed to be the TE mode, which has an electric field component perpendicular to the y direction. FIG. 6 shows the results of these calculations. Although the peaks in FIG. 6 differ slightly in position from the peaks for the TM mode (FIG. 2), they are located within the regions shown in FIG. 3. This demonstrates that the structure according to this embodiment is effective for both of the TM mode and the TE mode.

### 3-4. Two-Dimensional Periodic Structure

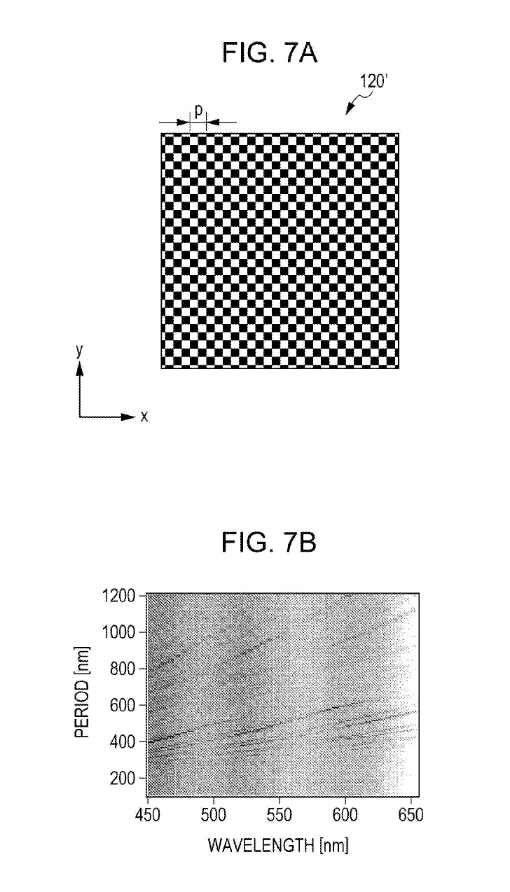

The effect of a two-dimensional periodic structure was also studied. FIG. 7A is a partial plan view of a two-dimensional periodic structure 120′ including recesses and projections arranged in both of the x direction and the y direction. In FIG. 7A, the black regions indicate the projections, and the white regions indicate the recesses. For a two-dimensional periodic structure, both of the diffraction in the x direction and the diffraction in the y direction have to be taken into account. Although the diffraction in only the x direction or the y direction is similar to that in a one-dimensional periodic structure, a two-dimensional periodic structure can be expected to give different results from a one-dimensional periodic structure because diffraction also occurs in a direction containing both of an x component and a y component (for example, a direction inclined at 45 degrees). FIG. 7B shows the calculation results of the enhancement of light for the two-dimensional periodic structure. The calculations were performed under the same conditions as in FIG. 2 except for the type of periodic structure. As shown in FIG. 7B, peaks matching the peaks for the TE mode in FIG. 6 were observed in addition to peaks matching the peaks for the TM mode in FIG. 2. These results demonstrate that the two-dimensional periodic structure also converts and outputs the TE mode by diffraction. For a two-dimensional periodic structure, the diffraction that simultaneously satisfies the first-order diffraction conditions in both of the x direction and the y direction also has to be taken into account. Such diffracted light is output in the direction at the angle corresponding to √2 times (that is, 2^{1/2} times) the period p. Thus, peaks will occur at √2 times the period p in addition to peaks that occur in a one-dimensional periodic structure. Such peaks are observed in FIG. 7B.

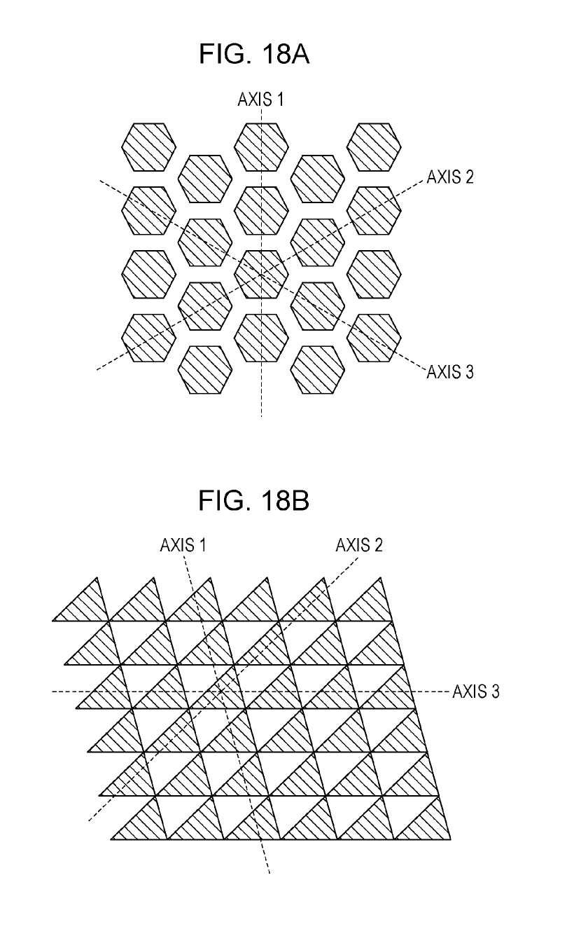

The two-dimensional periodic structure does not have to be a square grid structure having equal periods in the x direction and the y direction, as illustrated in FIG. 7A, but may be a hexagonal grid structure, as illustrated in FIG. 18A, or a triangular grid structure, as illustrated in FIG. 18B. The two-dimensional periodic structure may have different periods in different directions (for example, in the x direction and the y direction for a square grid structure).

In this embodiment, as demonstrated above, light in a characteristic quasi-guided mode formed by the periodic structure and the photoluminescent layer can be selectively output only in the front direction through diffraction by the periodic structure. With this structure, the photoluminescent layer can be excited with excitation light such as ultraviolet light or blue light to output directional light.

### 4. Study on Constructions of Periodic Structure and Photoluminescent Layer

The effects of changes in various conditions such as the constructions and refractive indices of the periodic structure and the photoluminescent layer will now be described.

### 4-1. Refractive Index of Periodic Structure

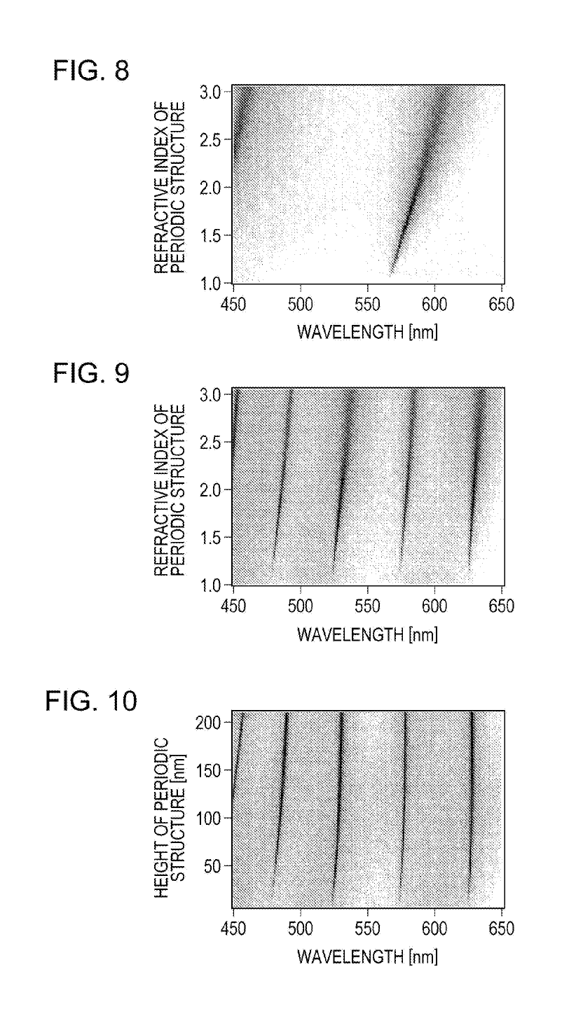

The refractive index of the periodic structure was studied. In the calculations performed herein, the photoluminescent layer was assumed to have a thickness of 200 nm and a refractive index n_{wav} of 1.8, the periodic structure was assumed to be a one-dimensional periodic structure uniform in the y direction, as shown in FIG. 1A, having a height of 50 nm and a period of 400 nm, and the polarization of the light was assumed to be the TM mode, which has an electric field component parallel to the y direction. FIG. 8 shows the calculation results of the enhancement of light output in the front direction with varying emission wavelengths and varying refractive indices of the periodic structure. FIG. 9 shows the results obtained under the same conditions except that the photoluminescent layer was assumed to have a thickness of 1,000 nm.

The results show that a photoluminescent layer having a thickness of 1,000 nm (FIG. 9) results in a smaller shift in the wavelength at which the light intensity peaks (referred to as a peak wavelength) with the change in the refractive index of the periodic structure than a photoluminescent layer having a thickness of 200 nm (FIG. 8). This is because the quasi-guided mode is more affected by the refractive index of the periodic structure as the photoluminescent layer is thinner. Specifically, a periodic structure having a higher refractive index increases the effective refractive index and thus shifts the peak wavelength toward longer wavelengths, and this effect is more noticeable as the photoluminescent layer is thinner. The effective refractive index is determined by the refractive index of the medium present in the region where the electric field of the quasi-guided mode is distributed.

The results also show that a periodic structure having a higher refractive index results in a broader peak and a lower intensity. This is because a periodic structure having a higher refractive index outputs light in the quasi-guided mode at a higher rate and is therefore less effective in confining the light, that is, has a lower Q value. To maintain a high peak intensity, a structure may be employed in which light is moderately output using a quasi-guided mode that is effective in confining the light (that is, has a high Q value). This means that it is undesirable to use a periodic structure made of a material having a much higher refractive index than the photoluminescent layer. Thus, in order to increase the peak intensity and Q value, the refractive index of a dielectric material constituting the periodic structure (that is, the light-transmissive layer) can be lower than or similar to the refractive index of the photoluminescent layer. This is also true if the photoluminescent layer contains materials other than photoluminescent materials.

### 4-2. Height of Periodic Structure

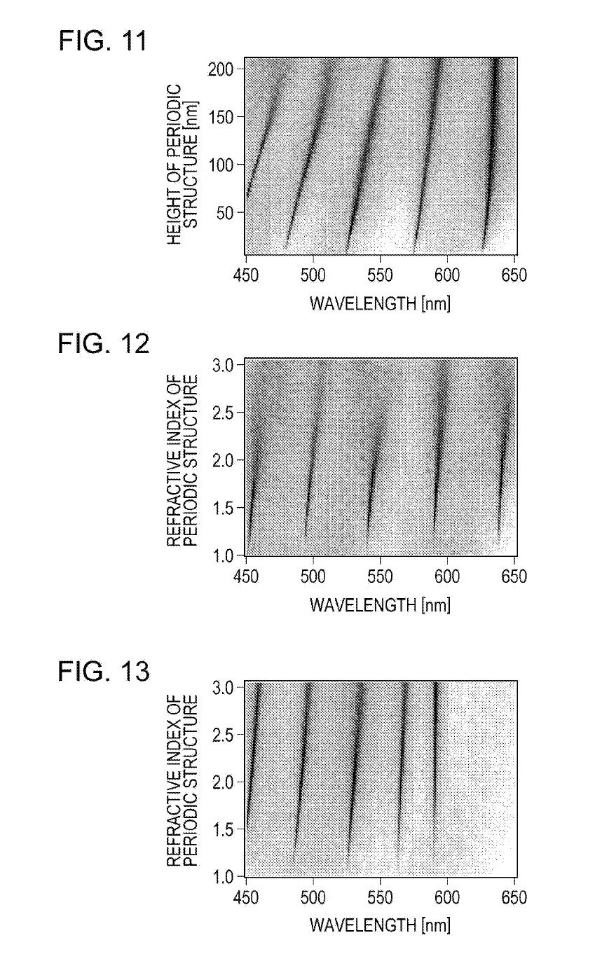

The height of the periodic structure was then studied. In the calculations performed herein, the photoluminescent layer was assumed to have a thickness of 1,000 nm and a refractive index n_{wav} of 1.8, the periodic structure was assumed to be a one-dimensional periodic structure uniform in the y direction, as shown in FIG. 1A, having a refractive index nₚ of 1.5 and a period of 400 nm, and the polarization of the light was assumed to be the TM mode, which has an electric field component parallel to the y direction. FIG. 10 shows the calculation results of the enhancement of light output in the front direction with varying emission wavelengths and varying heights of the periodic structure. FIG. 11 shows the results of calculations performed under the same conditions except that the periodic structure was assumed to have a refractive index nₚ of 2.0. Whereas the results in FIG. 10 show that the peak intensity and the Q value (that is, the peak line width) do not change above a certain height of the periodic structure, the results in FIG. 11 show that the peak intensity and the Q value decrease with increasing height of the periodic structure. If the refractive index n_{wav} of the photoluminescent layer is higher than the refractive index nₚ of the periodic structure (FIG. 10), the light is totally reflected, and only a leaking (that is, evanescent) portion of the electric field of the quasi-guided mode interacts with the periodic structure. If the periodic structure has a sufficiently large height, the influence of the interaction between the evanescent portion of the electric field and the periodic structure remains constant irrespective of the height. In contrast, if the refractive index n_{wav} of the photoluminescent layer is lower than the refractive index nₚ of the periodic structure (FIG. 11), the light reaches the surface of the periodic structure without being totally reflected and is therefore more influenced by a periodic structure with a larger height. As shown in FIG. 11, a height of approximately 100 nm is sufficient, and the peak intensity and the Q value decrease above a height of 150 nm. Thus, if the refractive index n_{wav} of the photoluminescent layer is lower than the refractive index nₚ of the periodic structure, the periodic structure may have a height of 150 nm or less to achieve a high peak intensity and Q value.

### 4-3. Polarization Direction

The polarization direction was then studied. FIG. 12 shows the results of calculations performed under the same conditions as in FIG. 9 except that the polarization of the light was assumed to be the TE mode, which has an electric field component perpendicular to the y direction. The TE mode is more influenced by the periodic structure than the TM mode because the electric field of the quasi-guided mode leaks more largely for the TE mode than for the TM mode. Thus, the peak intensity and the Q value decrease more significantly for the TE mode than for the TM mode if the refractive index nₚ of the periodic structure is higher than the refractive index n_{wav} of the photoluminescent layer.

### 4-4. Refractive Index of Photoluminescent Layer

The refractive index of the photoluminescent layer was then studied. FIG. 13 shows the results of calculations performed under the same conditions as in FIG. 9 except that the photoluminescent layer was assumed to have a refractive index n_{wav} of 1.5. The results for the photoluminescent layer having a refractive index n_{wav} of 1.5 are similar to the results in FIG. 9. However, light having a wavelength of 600 nm or more was not output in the front direction. This is because, from the inequality (10), λ₀<n_{wav}×p/m=1.5×400 nm/1=600 nm.

The above analysis demonstrates that a high peak intensity and Q value can be achieved if the periodic structure has a refractive index lower than or similar to the refractive index of the photoluminescent layer or if the periodic structure has a higher refractive index than the photoluminescent layer and a height of 150 nm or less.

### 5. Modified Examples

Modified Examples of the present embodiment will be described below.

### 5-1. Structure Including Substrate

As described above, the light-emitting device may have a structure in which the photoluminescent layer 110 and the periodic structure 120 are formed on the transparent substrate 140, as illustrated in FIGS. 1C and 1D. Such a light-emitting device 100a may be produced by forming a thin film of the photoluminescent material for the photoluminescent layer 110 (optionally containing a matrix material; the same applies hereinafter) on the transparent substrate 140 and then forming the periodic structure 120 thereon. In this structure, the refractive index nₛ of the transparent substrate 140 has to be lower than or equal to the refractive index n_{wav} of the photoluminescent layer 110 so that the photoluminescent layer 110 and the periodic structure 120 function to output light in a particular direction. If the transparent substrate 140 is provided in contact with the photoluminescent layer 110, the period p has to be set so as to satisfy the inequality (15), which is given by replacing the refractive index θₒᵤₜ of the output medium in the inequality (10) by nₛ.

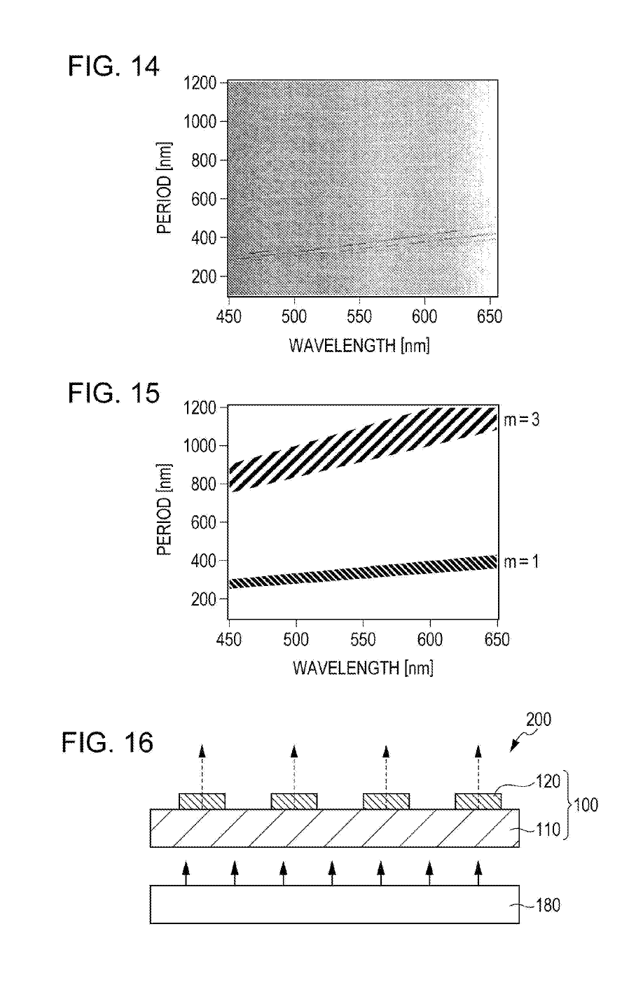

To demonstrate this, calculations were performed under the same conditions as in FIG. 2 except that the photoluminescent layer 110 and the periodic structure 120 were assumed to be located on a transparent substrate 140 having a refractive index of 1.5. FIG. 14 shows the results of these calculations. As in the results in FIG. 2, light intensity peaks are observed at particular periods for each wavelength, although the ranges of periods where peaks appear differ from those in FIG. 2. FIG. 15 is a graph illustrating the condition represented by the inequality (15), which is given by substituting nₒᵤₜ=nₛ into the inequality (10). In FIG. 14, light intensity peaks are observed in the regions corresponding to the ranges shown in FIG. 15.

Thus, for the light-emitting device 100a, in which the photoluminescent layer 110 and the periodic structure 120 are located on the transparent substrate 140, a period p that satisfies the inequality (15) is effective, and a period p that satisfies the inequality (13) is significantly effective.

### 5-2. Light-Emitting Apparatus Including Excitation Light Source

FIG. 16 is a schematic view of a light-emitting apparatus 200 including the light-emitting device 100 illustrated in FIGS. 1A and 1B and a light source 180 that emits excitation light toward the photoluminescent layer 110. In this embodiment, as described above, the photoluminescent layer can be excited with excitation light such as ultraviolet light or blue light to output directional light. The light source 180 can be configured to emit such excitation light to provide a directional light-emitting apparatus 200. Although the wavelength of the excitation light emitted from the light source 180 is typically within the ultraviolet or blue range, it is not necessarily within these ranges, but may be determined depending on the photoluminescent material for the photoluminescent layer 110. Although the light source 180 illustrated in FIG. 16 is configured to direct excitation light into the bottom surface of the photoluminescent layer 110, it may be configured otherwise, for example, to direct excitation light into the top surface of the photoluminescent layer 110.

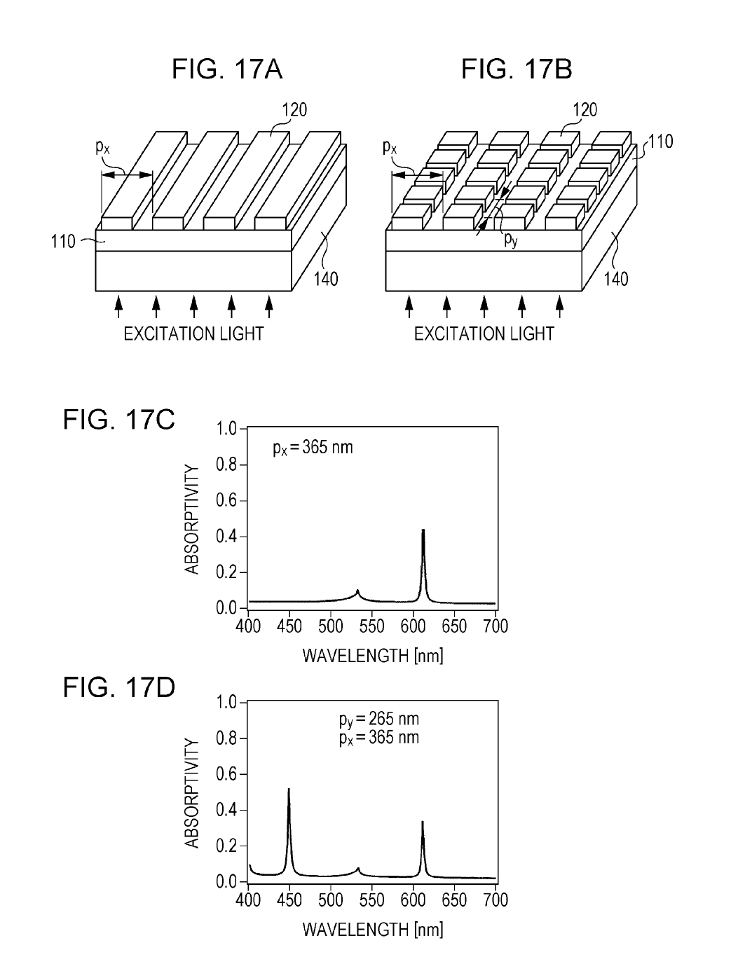

The excitation light may be coupled into a quasi-guided mode to efficiently output light. FIGS. 17A to 17D illustrate this method. In this example, as in the structure illustrated in FIGS. 1C and 1D, the photoluminescent layer 110 and the periodic structure 120 are formed on the transparent substrate 140. As illustrated in FIG. 17A, the period pₓ in the x direction is first determined so as to enhance light emission. As illustrated in FIG. 17B, the period p_{y} in the y direction is then determined so as to couple the excitation light into a quasi-guided mode. The period pₓ is determined so as to satisfy the condition given by replacing p in the inequality (10) by pₓ. The period p_{y} is determined so as to satisfy the inequality (16):

$$\frac{m {λ}_{ex}}{{n}_{wav}} < {p}_{y} < \frac{m {λ}_{ex}}{{n}_{out}} \qquad ( 16 )$$

wherein m is an integer of 1 or more, λₑₓ is the wavelength of the excitation light, and nₒᵤₜ is the refractive index of the medium having the highest refractive index of the media in contact with the photoluminescent layer 110 except the periodic structure 120.

In the example in FIGS. 17A to 17D, nₒᵤₜ is the refractive index nₛ of the transparent substrate 140. For a structure including no transparent substrate 140, as illustrated in FIG. 16, nₒᵤₜ denotes the refractive index of air (approximately 1.0).

In particular, the excitation light can be more effectively converted into a quasi-guided mode if m=1, that is, if the period p_{y} is determined so as to satisfy the inequality (17):

$$\frac{{λ}_{ex}}{{n}_{wav}} < {p}_{y} < \frac{{λ}_{ex}}{{n}_{out}} \qquad ( 17 )$$

Thus, the excitation light can be converted into a quasi-guided mode if the period p_{y} is set so as to satisfy the condition represented by the inequality (16) (particularly, the condition represented by the inequality (17)). As a result, the photoluminescent layer 110 can efficiently absorb the excitation light of the wavelength λₑₓ.

FIGS. 17C and 17D are the calculation results of the proportion of absorbed light to light incident on the structures illustrated in FIGS. 17A and 17B, respectively, for each wavelength. In these calculations, pₓ=365 nm, p_{y}=265 nm, the photoluminescent layer 110 was assumed to have an emission wavelength λ of about 600 nm, the excitation light was assumed to have a wavelength λₑₓ of about 450 nm, and the photoluminescent layer 110 was assumed to have an extinction coefficient of 0.003. As shown in FIG. 17D, the photoluminescent layer 110 has high absorptivity not only for the light emitted from the photoluminescent layer 110 but also for the excitation light, that is, light having a wavelength of approximately 450 nm. This indicates that the incident light is effectively converted into a quasi-guided mode to increase the proportion of the light absorbed into the photoluminescent layer 110. The photoluminescent layer 110 also has high absorptivity for the emission wavelength, that is, approximately 600 nm. This indicates that light having a wavelength of approximately 600 nm incident on this structure is similarly effectively converted into a quasi-guided mode. The periodic structure 120 shown in FIG. 17B is a two-dimensional periodic structure including structures having different periods (that is, different periodic components) in the x direction and the y direction. Such a two-dimensional periodic structure including periodic components allows for high excitation efficiency and high output intensity. Although the excitation light is incident on the transparent substrate 140 in FIGS. 17A and 17B, the same effect can be achieved even if the excitation light is incident on the periodic structure 120.

Also available are two-dimensional periodic structures including periodic components as shown in FIGS. 18A and 18B. The structure illustrated in FIG. 18A includes periodically arranged projections or recesses having a hexagonal planar shape. The structure illustrated in FIG. 18B includes periodically arranged projections or recesses having a triangular planar shape. These structures have major axes (axes 1 to 3 in the examples in FIGS. 18A and 18B) that can be assumed to be periodic. Thus, the structures can have different periods in different axial directions. These periods may be set so as to increase the directionality of light beams of different wavelengths or to efficiently absorb the excitation light. In any case, each period is set so as to satisfy the condition corresponding to the inequality (10).

### 5-3. Periodic Structure on Transparent Substrate

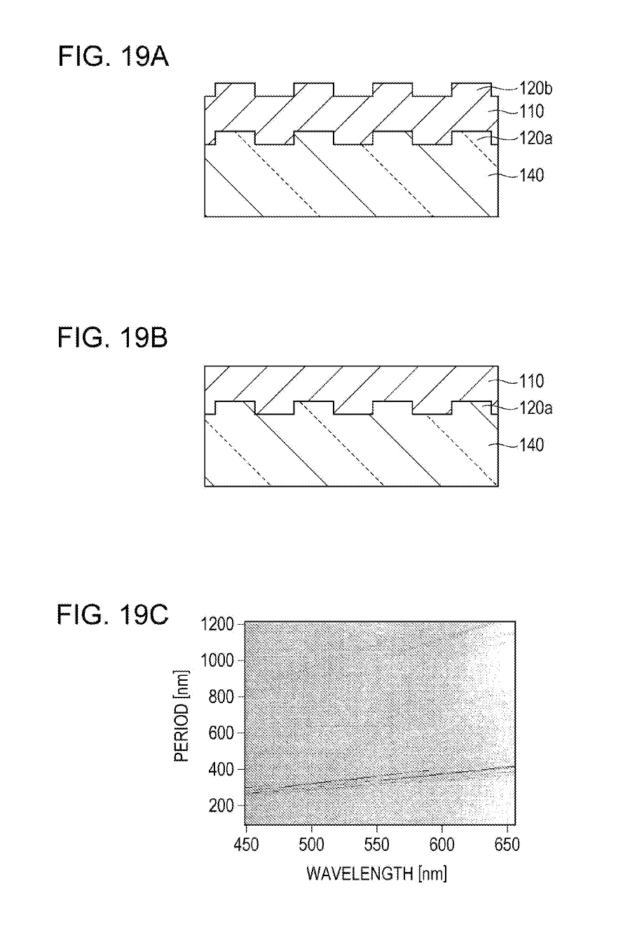

As illustrated in FIGS. 19A and 19B, a periodic structure 120a may be formed on the transparent substrate 140, and the photoluminescent layer 110 may be located thereon. In the example in FIG. 19A, the photoluminescent layer 110 is formed along the texture of the periodic structure 120a on the transparent substrate 140. As a result, a periodic structure 120b with the same period is formed in the surface of the photoluminescent layer 110. In the example in FIG. 19B, the surface of the photoluminescent layer 110 is flattened. In these examples, directional light emission can be achieved by setting the period p of the periodic structure 120a so as to satisfy the inequality (15).

To verify the effect of these structures, the enhancement of light output from the structure in FIG. 19A in the front direction was calculated with varying emission wavelengths and varying periods of the periodic structure. In these calculations, the photoluminescent layer 110 was assumed to have a thickness of 1,000 nm and a refractive index n_{wav} of 1.8, the periodic structure 120a was assumed to be a one-dimensional periodic structure uniform in the y direction having a height of 50 nm, a refractive index nₚ of 1.5, and a period of 400 nm, and the polarization of the light was assumed to be the TM mode, which has an electric field component parallel to the y direction. FIG. 19C shows the results of these calculations. In these calculations, light intensity peaks were observed at the periods that satisfy the condition represented by the inequality (15).

### 5-4. Powder

According to the above embodiment, light of any wavelength can be enhanced by adjusting the period of the periodic structure and the thickness of the photoluminescent layer. For example, if the structure illustrated in FIGS. 1A and 1B is formed using a photoluminescent material that emits light over a wide wavelength range, only light of a certain wavelength can be enhanced. Accordingly, the structure of the light-emitting device 100 as illustrated in FIGS. 1A and 1B may be provided in powder form for use as a fluorescent material. Alternatively, the light-emitting device 100 as illustrated in FIGS. 1A and 1B may be embedded in resin or glass.

The single structure as illustrated in FIGS. 1A and 1B can output only light of a certain wavelength in a particular direction and is therefore not suitable for outputting, for example, white light, which has a wide wavelength spectrum. Accordingly, as shown in FIG. 20, light-emitting devices 100 that differ in the conditions such as the period of the periodic structure and the thickness of the photoluminescent layer may be mixed in powder form to provide a light-emitting apparatus with a wide wavelength spectrum. In such a case, the individual light-emitting devices 100 have sizes of, for example, several micrometers to several millimeters in one direction and can include, for example, one- or two-dimensional periodic structures with several periods to several hundreds of periods.

### 5-5. Array of Structures Having Different Periods

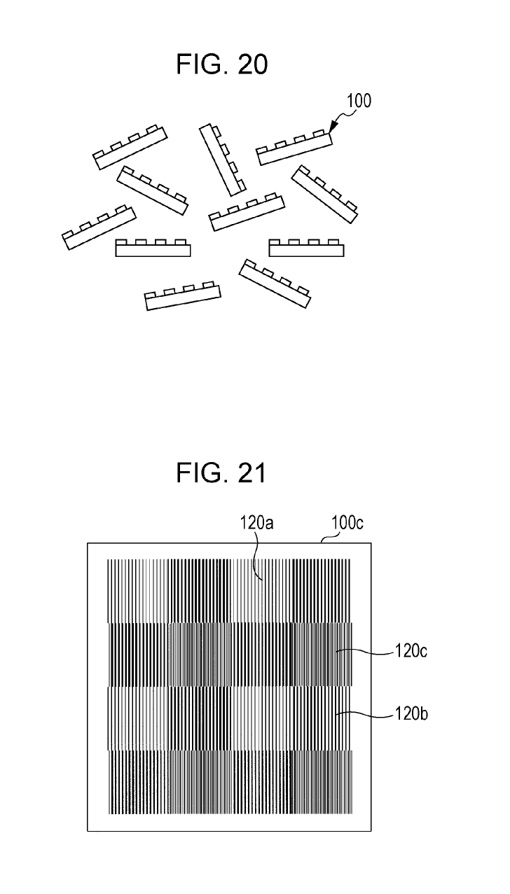

FIG. 21 is a plan view of a two-dimensional array of periodic structures having different periods on the photoluminescent layer. In this example, three types of periodic structures 120a, 120b, and 120c are arranged without any space therebetween. The periods of the periodic structures 120a, 120b, and 120c are set so as to output, for example, light in the red, green, and blue wavelength ranges, respectively, in the front direction. Thus, structures having different periods can be arranged on the photoluminescent layer to output directional light with a wide wavelength spectrum. The periodic structures are not necessarily configured as described above, but may be configured in any manner.

### 5-6. Layered Structure

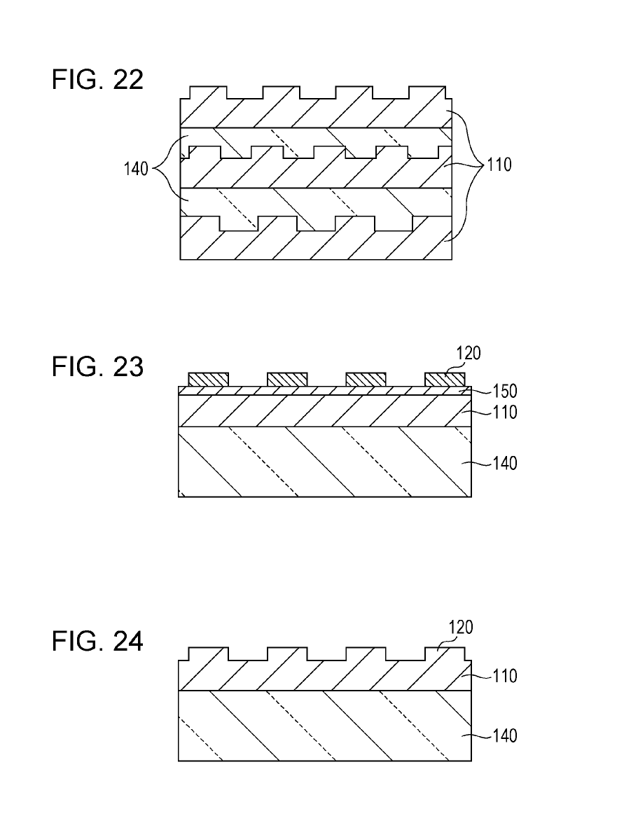

FIG. 22 illustrates a light-emitting device including photoluminescent layers 110 each having a textured surface. A transparent substrate 140 is located between the photoluminescent layers 110. The texture on each of the photoluminescent layers 110 corresponds to the periodic structure or the submicron structure. The example in FIG. 22 includes three periodic structures having different periods. The periods of these periodic structures are set so as to output light in the red, green, and blue wavelength ranges in the front direction. The photoluminescent layer 110 in each layer is made of a material that emits light of the color corresponding to the period of the periodic structure in that layer. Thus, periodic structures having different periods can be stacked on top of each other to output directional light with a wide wavelength spectrum.

The number of layers and the constructions of the photoluminescent layer 110 and the periodic structure in each layer are not limited to those described above, but may be selected as appropriate. For example, for a structure including two layers, first and second photoluminescent layers are formed opposite each other with a light-transmissive substrate therebetween, and first and second periodic structures are formed on the surfaces of the first and second photoluminescent layers, respectively. In such a case, the first photoluminescent layer and the first periodic structure may together satisfy the condition corresponding to the inequality (15), whereas the second photoluminescent layer and the second periodic structure may together satisfy the condition corresponding to the inequality (15). For a structure including three or more layers, the photoluminescent layer and the periodic structure in each layer may satisfy the condition corresponding to the inequality (15). The positional relationship between the photoluminescent layers and the periodic structures in FIG. 22 may be reversed. Although the layers illustrated by the example in FIG. 22 have different periods, they may all have the same period. In such a case, although the spectrum cannot be broadened, the emission intensity can be increased.

### 5-7. Structure Including Protective Layer

FIG. 23 is a cross-sectional view of a structure including a protective layer 150 between the photoluminescent layer 110 and the periodic structure 120. The protective layer 150 may be provided to protect the photoluminescent layer 110. However, if the protective layer 150 has a lower refractive index than the photoluminescent layer 110, the electric field of the light leaks into the protective layer 150 only by about half the wavelength. Thus, if the protective layer 150 is thicker than the wavelength, no light reaches the periodic structure 120. As a result, there is no quasi-guided mode, and the function of outputting light in a particular direction cannot be achieved. If the protective layer 150 has a refractive index higher than or similar to that of the photoluminescent layer 110, the light reaches the interior of the protective layer 150; therefore, there is no limitation on the thickness of the protective layer 150. Nevertheless, a thinner protective layer 150 is desirable because more light is output if most of the portion in which light is guided (this portion is hereinafter referred to as “waveguide layer”) is made of a photoluminescent material. The protective layer 150 may be made of the same material as the periodic structure (light-transmissive layer) 120. In such a case, the light-transmissive layer 120 having the periodic structure functions as a protective layer. The light-transmissive layer 120 desirably has a lower refractive index than the photoluminescent layer 110.

### 6. Materials and Production Methods

Directional light emission can be achieved if the photoluminescent layer (or waveguide layer) and the periodic structure are made of materials that satisfy the above conditions. The periodic structure may be made of any material. However, a photoluminescent layer (or waveguide layer) or a periodic structure made of a medium with high light absorption is less effective in confining light and therefore results in a lower peak intensity and Q value. Thus, the photoluminescent layer (or waveguide layer) and the periodic structure may be made of media with relatively low light absorption.

For example, the periodic structure may be formed of a dielectric material having low light absorptivity. Examples of candidate materials for the periodic structure include magnesium fluoride (MgF₂), lithium fluoride (LiF), calcium fluoride (CaF₂), quartz (SiO₂), glasses, resins, magnesium oxide (MgO), indium tin oxide (ITO), titanium oxide (TiO₂), silicon nitride (SiN), tantalum pentoxide (Ta₂O₅), zirconia (ZrO₂), zinc selenide (ZnSe), and zinc sulfide (ZnS). To form a periodic structure having a lower refractive index than the photoluminescent layer, as described above, MgF₂, LiF, CaF₂, SiO₂, glasses, and resins can be used, which have refractive indices of approximately 1.3 to 1.5.

The term “photoluminescent material” encompasses fluorescent materials and phosphorescent materials in a narrow sense, encompasses inorganic materials and organic materials (for example, dyes), and encompasses quantum dots (that is, tiny semiconductor particles). In general, a fluorescent material containing an inorganic host material tends to have a higher refractive index. Examples of fluorescent materials that emit blue light include M₁₀(PO₄)₆Cl₂:Eu²⁺ (wherein M is at least one element selected from Ba, Sr, and Ca), BaMgAl₁₀O₁₇:Eu²⁺, M₃MgSi₂O₅:Eu²⁺ (wherein M is at least one element selected from Ba, Sr, and Ca), and M₅SiO₄Cl₆:Eu²⁺ (wherein M is at least one element selected from Ba, Sr, and Ca). Examples of fluorescent materials that emit green light include M₂MgSi₂O₇:Eu²⁺ (wherein M is at least one element selected from Ba, Sr, and Ca), SrSi₅AlO₂N₇:Eu²⁺, SrSi₂O₂N₂:Eu²⁺, BaAl₂O₄:Eu²⁺, BaZrSi₃O₉:Eu²⁺, M₂SiO₄:Eu²⁺ (wherein M is at least one element selected from Ba, Sr, and Ca), BaSi₃O₄N₂:Eu²⁺, Ca₈Mg(SiO₄)₄Cl₂:Eu²⁺, Ca₃SiO₄Cl₂:Eu²⁺, CaSi₁₂₋₍ₘ₊ₙ₎Al₍ₘ₊ₙ₎OₙN₁₆₋ₙ:Ce³⁺, and β-SiAlON:Eu²⁺. Examples of fluorescent materials that emit red light include CaAlSiN₃:Eu²⁺, SrAlSi₄O₇:Eu²⁺, M₂Si₅N₅:Eu²⁺ (wherein M is at least one element selected from Ba, Sr, and Ca), MSiN₂:Eu²⁺ (wherein M is at least one element selected from Ba, Sr, and Ca), MSi₂O₂N₂:Yb²⁺ (wherein M is at least one element selected from Sr and Ca), Y₂O₂S:Eu³⁺,Sm³⁺, La₂O₂S:Eu³⁺,Sm³⁺, CaWO₄:Li¹⁺,Eu³⁺,Sm³⁺, M₂SiS₄:Eu²⁺ (wherein M is at least one element selected from Ba, Sr, and Ca), and M₃SiO₅:Eu²⁺ (wherein M is at least one element selected from Ba, Sr, and Ca). Examples of fluorescent materials that emit yellow light include Y₃Al₅O₁₂:Ce³⁺, CaSi₂O₂N₂:Eu²⁺, Ca₃Sc₂Si₃O₁₂:Ce³⁺, CaSc₂O₄:Ce³⁺, α-SiAlON:Eu²⁺, MSi₂O₂N₂:Eu²⁺ (wherein M is at least one element selected from Ba, Sr, and Ca), and M₇(SiO₃)₆Cl₂:Eu²⁺ (wherein M is at least one element selected from Ba, Sr, and Ca).

Examples of quantum dots include materials such as CdS, CdSe, core-shell CdSe/ZnS, and alloy CdSSe/ZnS. Light of various wavelengths can be emitted depending on the material. Examples of matrices for quantum dots include glasses and resins.

The transparent substrate 140, as shown in, for example, FIGS. 1C and 1D, is made of a light-transmissive material having a lower refractive index than the photoluminescent layer 110. Examples of such materials include magnesium fluoride (MgF₂), lithium fluoride (LiF), calcium fluoride (CaF₂), quartz (SiO₂), glasses, and resins.

Exemplary production methods will be described below.

A method for forming the structure illustrated in FIGS. 1C and 1D includes forming a thin film of the photoluminescent layer 110 on the transparent substrate 140, for example, by evaporation, sputtering, or coating of a fluorescent material, forming a dielectric film, and then patterning the dielectric film, for example, by photolithography to form the periodic structure 120. Alternatively, the periodic structure 120 may be formed by nanoimprinting. As shown in FIG. 24, the periodic structure 120 may also be formed by partially processing the photoluminescent layer 110. In such a case, the periodic structure 120 is made of the same material as the photoluminescent layer 110.

The light-emitting device 100 illustrated in FIGS. 1A and 1B can be manufactured, for example, by fabricating the light-emitting device 100a illustrated in FIGS. 1C and 1D and then stripping the photoluminescent layer 110 and the periodic structure 120 from the substrate 140.

The structure shown in FIG. 19A can be manufactured, for example, by forming the periodic structure 120a on the transparent substrate 140 by a process such as a semiconductor manufacturing processes or nanoimprinting and then depositing thereon the material for the photoluminescent layer 110 by a process such as evaporation or sputtering. The structure shown in FIG. 19B can be manufactured by filling the recesses in the periodic structure 120a with the photoluminescent layer 110 by a process such as coating.

The above methods of manufacture are for illustrative purposes only, and the light-emitting devices according to the embodiments of the present disclosure may be manufactured by other methods.

### EXPERIMENTAL EXAMPLES

Light-emitting devices according to embodiments of the present disclosure are illustrated by the following examples.

A sample light-emitting device having the structure as illustrated in FIG. 19A was prepared and evaluated for its properties. The light-emitting device was prepared as described below.

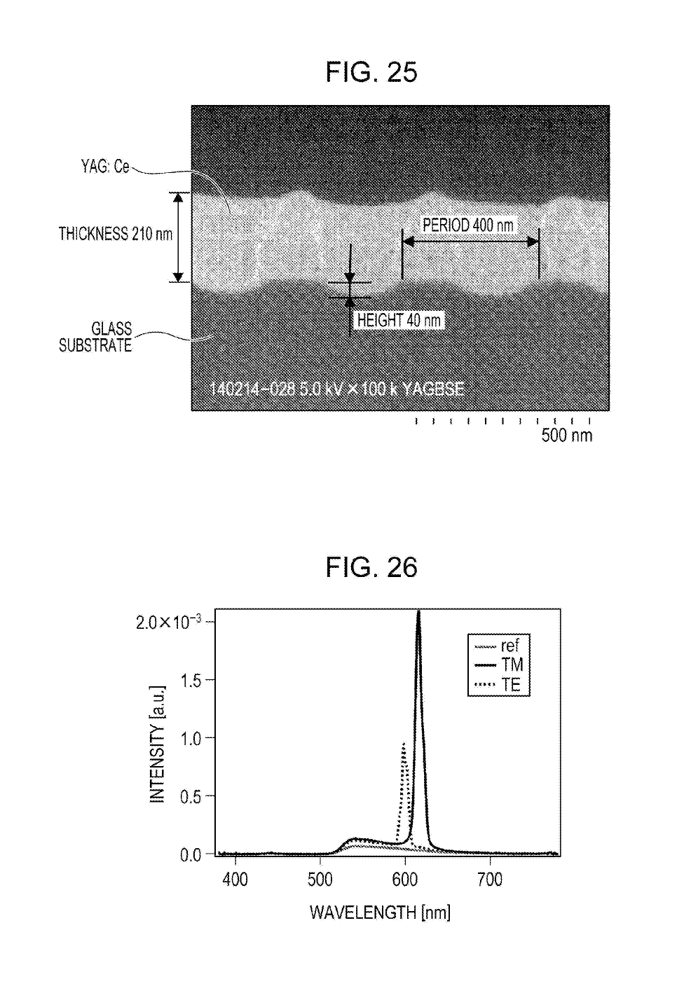

A one-dimensional periodic structure (stripe-shaped projections) having a period of 400 nm and a height of 40 nm was formed on a glass substrate, and a photoluminescent material, that is, YAG:Ce, was deposited thereon to a thickness of 210 nm. FIG. 25 shows a cross-sectional transmission electron microscopy (TEM) image of the resulting light-emitting device. FIG. 26 shows the results of measurements of the spectrum of light emitted from the light-emitting device in the front direction when YAG:Ce was excited with an LED having an emission wavelength of 450 nm. FIG. 26 shows the results (ref) for a light-emitting device including no periodic structure, the results for the TM mode, and the results for the TE mode. The TM mode has a polarization component parallel to the one-dimensional periodic structure. The TE mode has a polarization component perpendicular to the one-dimensional periodic structure. The results show that the intensity of light of a particular wavelength in the case with the periodic structure is significantly higher than without a periodic structure. The results also show that the light enhancement effect is greater for the TM mode, which has a polarization component parallel to the one-dimensional periodic structure.

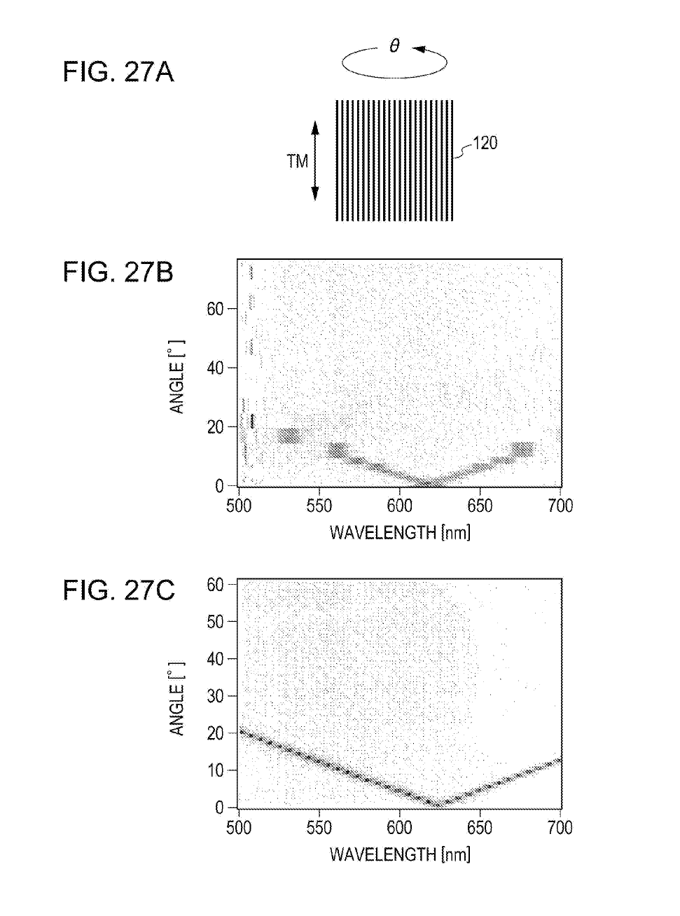

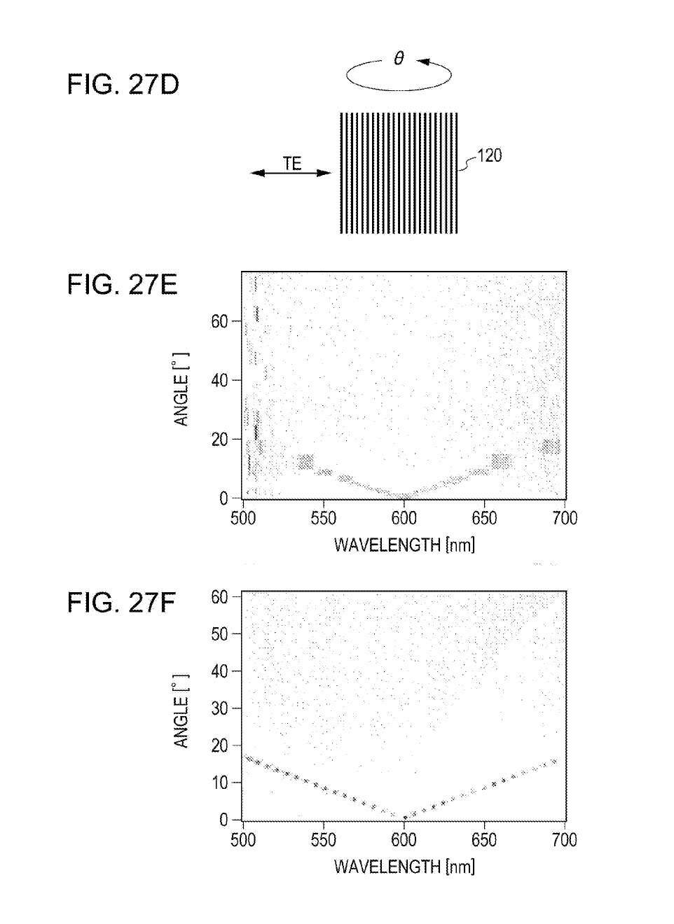

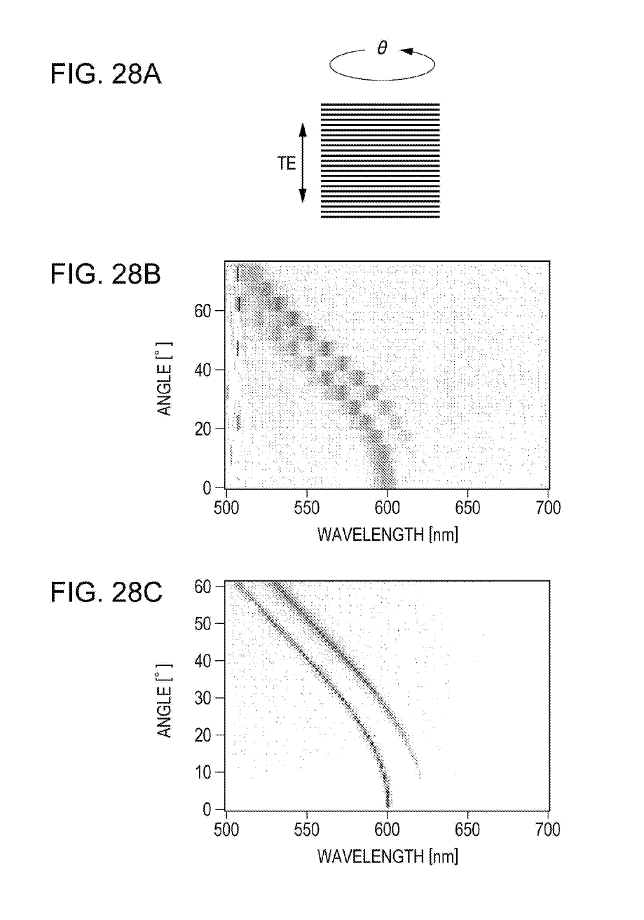

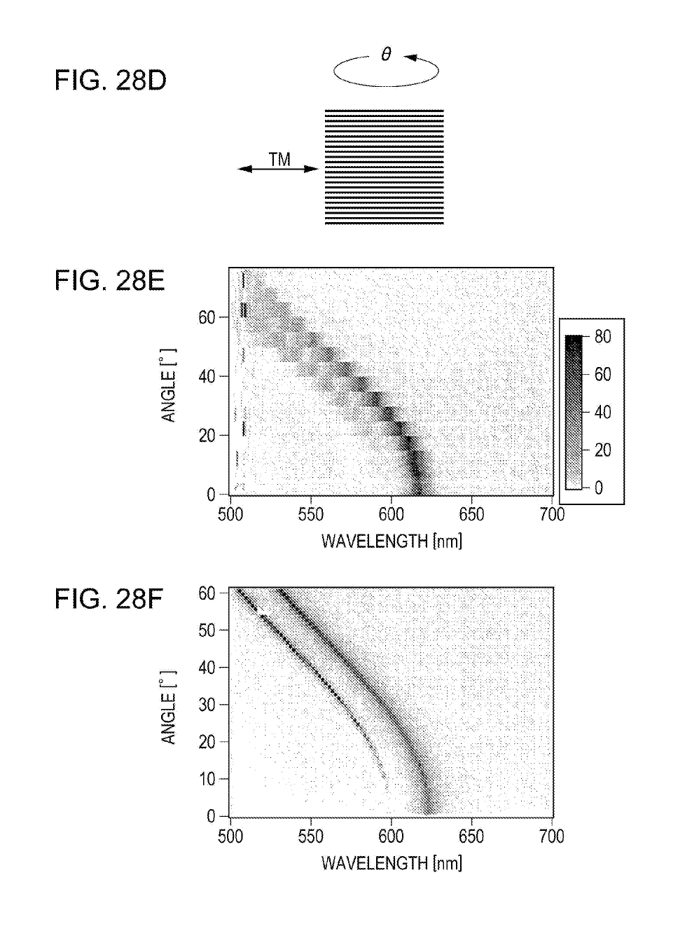

FIGS. 27A to 27F and FIGS. 28A to 28F show the results of measurements and calculations of the angular dependence of the intensity of light output from the same sample. FIGS. 27B and 27E show the results of measurements and FIGS. 27C and 27F show the results of calculations for rotation about an axis parallel to the line direction of the one-dimensional periodic structure (that is, the periodic structure 120). FIGS. 28B and 28E show the results of measurements and FIGS. 28C and 28F show the results of calculations for rotation about an axis perpendicular to the line direction of the one-dimensional periodic structure (that is, the periodic structure 120). FIGS. 27A to 27F and FIGS. 28A to 28F show the results for linearly polarized light in the TM mode and the TE mode. FIG. 27A shows the results for linearly polarized light in the TM mode. FIGS. 27D to 27F show the results for linearly polarized light in the TE mode. FIGS. 28A to 28C show the results for linearly polarized light in the TE mode. FIGS. 28D to 28F show the results for linearly polarized light in the TM mode. As can be seen from FIGS. 27A to 27F and FIGS. 28A to 28F, the enhancement effect is greater for the TM mode, and the enhanced wavelength shifts with angle. For example, light having a wavelength of 610 nm is observed only in the TM mode and in the front direction, indicating that the light is directional and polarized. In addition, the top and bottom parts of each figure match each other. Thus, the validity of the above calculations was experimentally demonstrated.

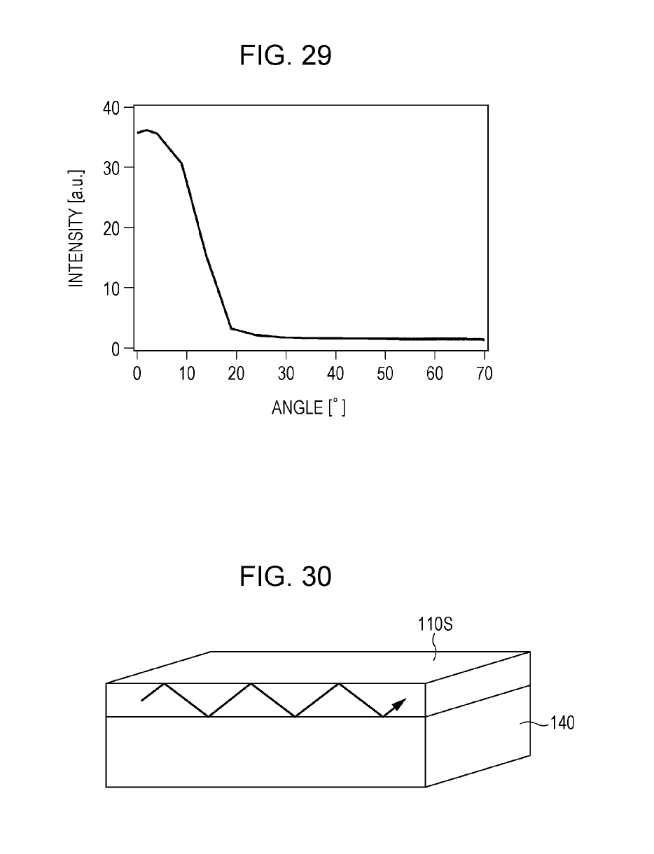

Among the above results of measurements, for example, FIG. 29 shows the angular dependence of the intensity of light having a wavelength of 610 nm for rotation about an axis perpendicular to the line direction. As shown in FIG. 29, the light was significantly enhanced in the front direction and was little enhanced at other angles. The directional angle of the light output in the front direction is less than 15 degrees. The directional angle is the angle at which the intensity is 50% of the maximum intensity and is expressed as the angle of one side with respect to the direction with the maximum intensity. This demonstrates that directional light emission was achieved. In addition, all the light was in the TM mode, which demonstrates that polarized light emission was simultaneously achieved.

Although YAG:Ce, which emits light in a wide wavelength range, was used in the above experiment, directional and polarized light emission can also be achieved using a similar structure including a photoluminescent material that emits light in a narrow wavelength range. Such a photoluminescent material does not emit light of other wavelengths and can therefore be used to provide a light source that does not emit light in other directions or in other polarized states.

Modified examples of a light-emitting device and a light-emitting apparatus according to the present disclosure will be described below. A light-emitting device that has periodic structures, enhances light having different wavelengths, and/or emits enhanced light in different directions will be described below. Although an exemplary structure and operation of a light-emitting device having periodic structures have been described with reference to FIG. 22, other variations will be described below.

Like the light-emitting devices described above, the following light-emitting device includes a photoluminescent layer 110, a light-transmissive layer 120 located on or near the photoluminescent layer 110, and a submicron structure that is formed on at least one of the photoluminescent layer 110 and the light-transmissive layer 120 and extends in a plane of the photoluminescent layer 110 or the light-transmissive layer 120. The submicron structure includes at least two periodic structures formed of projections or recesses. Light emitted from the photoluminescent layer 110 includes first light having a wavelength λₐ in air and second light having a wavelength λ_{b} in air. The at least two periodic structures include a first periodic structure having a first period pₐ that satisfies λₐ/n_{wav-a}<pₐ<λₐ and a second periodic structure having a second period p_{b} that satisfies λ_{b}/n_{wav-b}<p_{b}<λ_{b}, wherein n_{wav-a} and n_{wav-b} denote refractive indices of the photoluminescent layer 110 for the first light and the second light, respectively. The first light (having a wavelength of λₐ) and the second light (having a wavelength of λ_{b}) may be the same or different. The first period pₐ and the second period p_{b} may be the same or different. The two representative periods (the first period and the second period) of the two periodic structures (the first periodic structure and the second periodic structure) are the minimum periods of the periodic structures.

### Stacking of Structures Having Same Period

Although photoluminescent layers each having a periodic structure are stacked in the light-emitting device having the structure illustrated in FIG. 22, periodic structures may be formed on one photoluminescent layer, as illustrated in FIGS. 31A and 31B.

A light-emitting device 100A in FIG. 31A includes a first periodic structure 120A on a top surface of the photoluminescent layer 110 and a second periodic structure 120B on a bottom surface of the photoluminescent layer 110. The two periodic structures 120A and 120B are formed as light-transmissive layers. The periodic structures 120A and 120B may be independently formed of the material of the photoluminescent layer 110. It is desirable that the light-transmissive layers have a lower refractive index than the photoluminescent layer 110.

The first period pₐ of the first periodic structure 120A is equal to the second period p_{b} of the second periodic structure 120B (pₐ=p_{b}). Thus, the first periodic structure 120A and the second periodic structure 120B can improve the directionality of light having the same wavelength (λₐ=λ_{b}). However, the direction of periodicity of the first periodic structure 120A is different from the direction of periodicity of the second periodic structure 120B. Thus, the direction of improved directionality due to the first periodic structure 120A is different from the direction of improved directionality due to the second periodic structure 120B. Thus, as in the light-emitting device 100A, periodic structures having the same period and different directions of periodicity can be combined to achieve a plurality of directions of improved directionality. Consequently, such a light-emitting device can have improved directionality in more directions. As described herein, when the direction of periodicity of the first periodic structure 120A is perpendicular to the direction of periodicity of the second periodic structure 120B, the direction of linear polarization of improved directionality due to the first periodic structure 120A is perpendicular to the direction of linear polarization of improved directionality due to the second periodic structure 120B. Thus, unpolarized light can be emitted.

As in the light-emitting device 100B illustrated in FIG. 31B, the periodic structure 120B on a bottom surface of the photoluminescent layer 110 may be formed on a substrate 140 or may be integrated with the substrate 140.

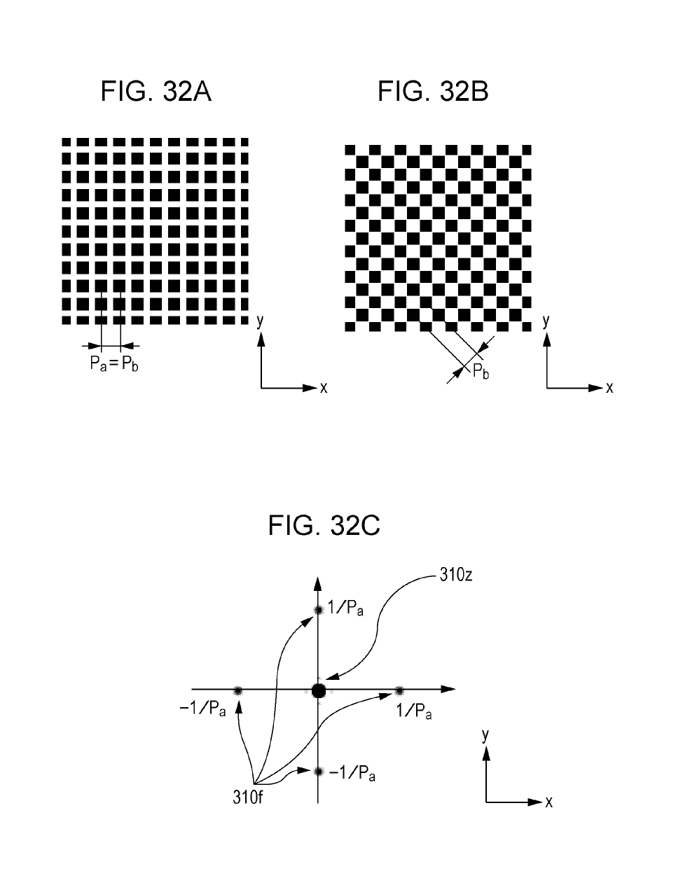

A structure having such periodicity may be a two-dimensionally arranged pattern illustrated in FIG. 32A or 32B. FIG. 32A is a plan view of a square grid pattern of a two-dimensional periodic structure having periodicity in the vertical direction (y direction) and the horizontal direction (x direction) in the drawing. FIG. 32B is a plan view of a checkered pattern (checked pattern) of a two-dimensional periodic structure having periodicity in a direction corresponding to a 45 degree rotation in FIG. 32A. The period p_{b} (inclined at 45 degrees) of the checkered pattern in FIG. 32B is equal to the period pₐ (the same in the vertical and horizontal directions) of the square grid pattern in FIG. 32A. Each pattern is composed of quadrangular prismatic projections (black portions) having a square shape when viewed from the top. Thus, the number of directions of periodicity can be increased, and the light-emitting device can have improved directionality in more directions.

### Pattern Synthesis

Although a periodic structure is formed on the top and bottom of the photoluminescent layer in the example described above, periodic structures may be superposed on a surface. Periodic structures may be formed on the same surface of at least one of the photoluminescent layer 110 and the light-transmissive layer 120. This corresponds to a pattern including superposed periodic structure patterns. Periodic structure patterns can be superposed using logical operation.

### Method for Analyzing Patterns to be Synthesized

First, refer to FIGS. 32A and 32C. FIG. 32A is a plan view of a square grid pattern of a two-dimensional periodic structure. In the square grid pattern of the two-dimensional periodic structure in FIG. 32A, a quadrangular prismatic projection (a black portion in the figure) having a square shape when viewed from the top is located at each grid point of the square grid. White portions in the figure are recesses. FIG. 32C shows the distribution of the intensity (a square of the absolute value of amplitude) of a spatial frequency component of the periodic structure obtained by Fourier transformation of the pattern in FIG. 32A. In FIG. 32C, the central point 310z indicates a component having a spatial frequency of 0, and an outer component has a higher spatial frequency. The intensity of a spatial frequency component is shown with shading; a darker (black) component has higher intensity, and a lighter (white) component has lower intensity. In general, FIG. 32C is known as a diffraction pattern obtained from the periodic structure in FIG. 32A. The central point in FIG. 32C corresponds to 0-order light. FIG. 32C does not show the intensity distribution of light emitted from a light-emitting device according to the present disclosure. The distribution of spatial frequency intensity of a periodic structure shown in FIG. 32C is used to examine the periodic structure of a light-emitting device according to the present disclosure.

In FIG. 32C, the central point 310z indicates an offset component having a spatial frequency of 0. The central point 310z, which corresponds to a structure having no periodicity, does not cause the effect of improving the directionality of a light-emitting device according to the present disclosure. The structure contributing to the effect of improving the directionality of a light-emitting device according to the present disclosure is a periodic structure corresponding to points 310f (corresponding to 1-order light in the diffraction pattern) observed in a peripheral region in FIG. 32C.

The four points 310f in FIG. 32C are located at positions corresponding to the period (pitch, the same in the vertical and horizontal directions) of the square grid in the (vertical and horizontal) directions of periodicity of the square grid in FIG. 32A. The four points are located at a distance of 1/Pₐ from the central point 310z and are point-symmetrical with respect to the central point 310z. More specifically, the points corresponding to a periodic structure having periodicity in the horizontal direction (in the x direction) appear as a pair of points located at a distance of 1/Pₐ from the central point 310z in the +x direction and in the −x direction. The points corresponding to a periodic structure having periodicity in the vertical direction (in the y direction) appear as a pair of points located at a distance of 1/Pₐ from the central point 310z in the +y direction and in the −y direction.

Thus, the direction of high periodicity (the in-plane direction of the two-dimensional pattern) and the period of the two-dimensional periodic structure can be determined from the distribution of spatial frequency intensity. More specifically, the four points 310f in FIG. 32C appear as a pair of two points at equal distances (1/Pₐ) from the central point 310z in the vertical direction and a pair of two points at equal distances (1/Pₐ) from the central point 310z in the horizontal direction. Thus, there is periodicity in the vertical and horizontal directions, and the period is Pₐ that is the same in the vertical and horizontal directions. In contrast, there is no point having high spatial frequency intensity in oblique directions in FIG. 32C. Thus, the two-dimensional periodic structure in FIG. 32A has low periodicity in oblique directions.

These show that a light-emitting device according to the present disclosure having the two-dimensional periodic structure illustrated in FIG. 32A can have improved directionality of emitted light in the vertical and horizontal directions in FIG. 32A but cannot have improved directionality of emitted light in oblique directions.

### Analysis of Synthesized Pattern

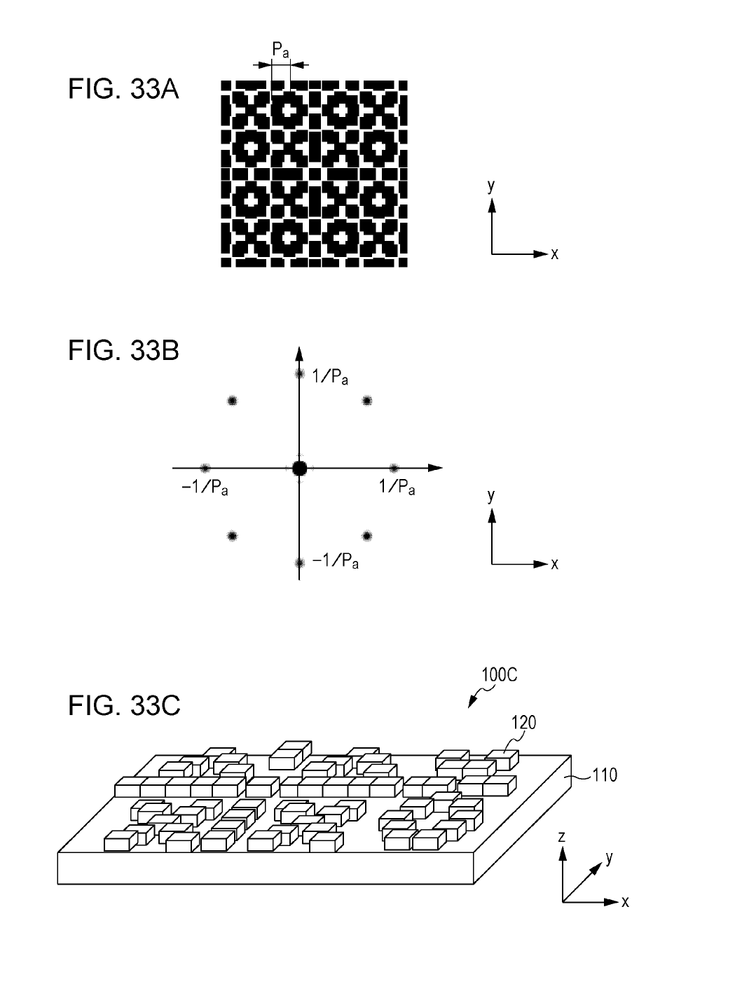

Next, refer to FIGS. 33A and 33B. FIG. 33A is a plan view of a pattern of a two-dimensional periodic structure including periodic structures having different directions of periodicity. FIG. 33B shows the distribution of spatial frequency intensity of the periodic structure obtained by Fourier transformation of the pattern in FIG. 33A.

The pattern in FIG. 33A is obtained by superposition of the first periodic pattern in FIG. 32A and the second periodic pattern in FIG. 32B using logical operation. For example, in each pattern, the projections are taken as “1 (true)”, and the recesses are taken as “0 (false)”. The operations of 1+0=1, 1+1=1, and 0+0=0 are performed in each point on the plane. The pattern in FIG. 33A is obtained by logical operation of the superposed first and second periodic patterns having almost the same period while they have different period directions.

FIG. 33B shows that the distribution of spatial frequency intensity of a two-dimensional periodic structure having the pattern in FIG. 33A includes a component having a spatial frequency of 0 as a central point and points derived from the first and second periodic patterns at equal distances (1/Pₐ) from the central point. This results from the synthesis of two periodic patterns having the same period (Pₐ). The points derived from the first and second periodic patterns are located on a concentric circle (having a radius of 1/Pₐ) at regular intervals around the central point of the component having a spatial frequency of 0. As described above, the periodic square grid pattern in FIG. 32A forms four points (two pairs): a pair of two points at equal distances (1/Pₐ) from the central point in the vertical direction and a pair of two points at equal distances (1/Pₐ) from the central point in the horizontal direction. The pattern in FIG. 32B also forms four points in the same manner. On the assumption that the angle increases counterclockwise with respect to the +x direction, which is taken as 0 degrees, a pair of two points at equal distances (1/Pₐ) from the central point are located at 45 and 225 degrees, and a pair of two points at equal distances (1/Pₐ) from the central point are located at 135 and 315 degrees. Thus, the pattern in FIG. 33A obtained by logical operation of the superposed patterns in FIG. 32A and FIG. 32B forms eight points on a concentric circle, as illustrated in FIG. 33B.

As illustrated in FIG. 33C, a light-transmissive layer (periodic structure) 120 having the pattern thus formed can be located on a surface of a photoluminescent layer 110. This can increase the number of directions of periodicity. Thus, such a light-emitting device can have improved directionality in more directions. This can decrease the number of processes for forming a periodic structure and the number of man-hours.

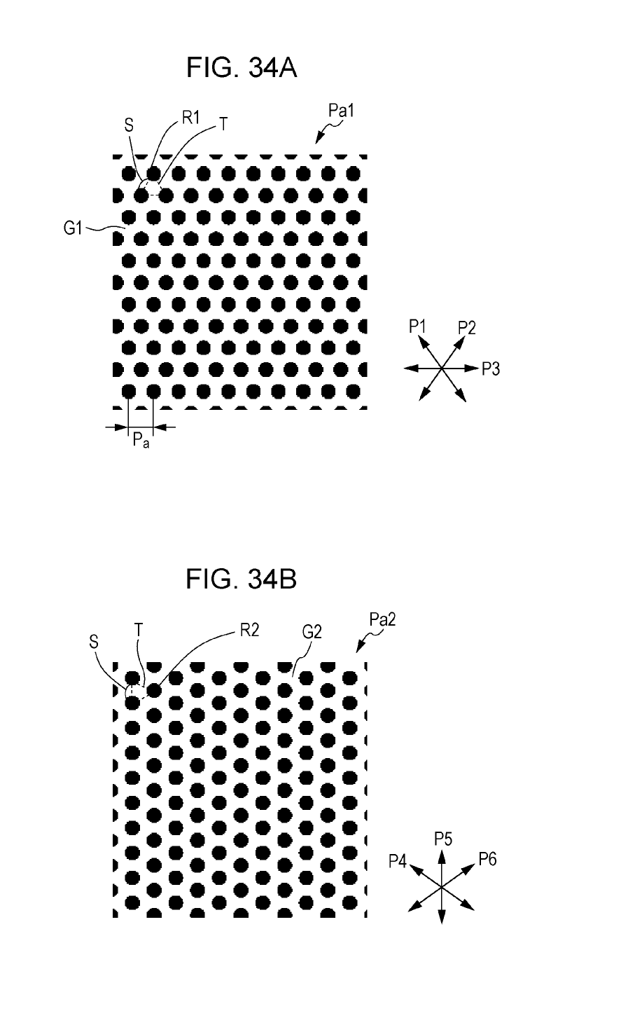

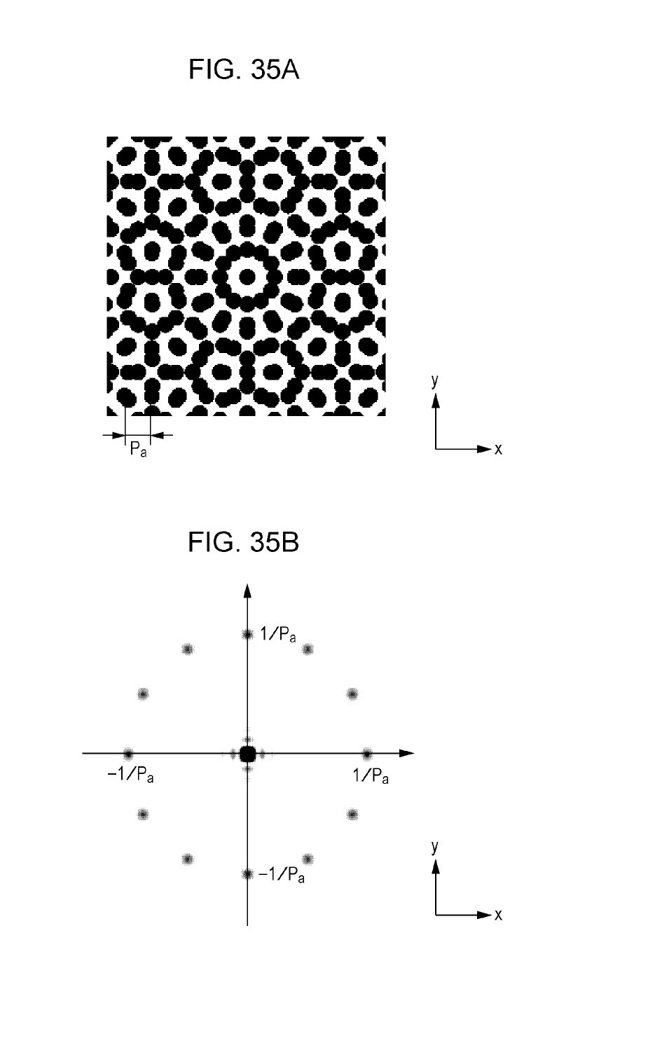

The patterns to be superposed by logical operation are not particularly limited and may be any patterns. For example, see FIGS. 34A and 34B and FIGS. 35A and 35B. FIGS. 34A and 34B are plan views of patterns Pa1 and Pa2 of a two-dimensional periodic structure including periodic structures having different directions of periodicity. FIG. 35A is a plan view of a pattern obtained as a logical sum of the patterns in FIGS. 34A and 34B. FIG. 35B shows the distribution of spatial frequency intensity of the periodic structure obtained by Fourier transformation of the pattern in FIG. 35A.

The pattern in FIG. 35A is obtained by superposition of the first periodic pattern Pa1 in FIG. 34A and the second periodic pattern Pa2 in FIG. 34B using logical operation. The first periodic pattern Pa1 in FIG. 34A includes circular first projections R1 at grid points of a triangular grid T in a first recess (a white region) G1. The second periodic pattern Pa2 in FIG. 34B includes circular second projections R2 at grid points of a triangular grid T in a second recess (a white region) G2.

The first projections R1 are periodically arranged in period directions P1, P2, and P3 that form an angle of 60 degrees with each other. The second projections R2 are periodically arranged in period directions P4, P5, and P6 that form an angle of 60 degrees with each other. The period of the first projections R1 is equal to the period of the second projections R2. Each of the period directions P1, P2, and P3 forms an angle of 30+60n (n is an integer of 0 or more) degrees with each of the period directions P4, P5, and P6.

The pattern in FIG. 35A is obtained by logical operation of the superposed first periodic pattern Pa1 and second periodic pattern Pa2 having almost the same period while they have different period directions.

FIG. 35B shows that the distribution of spatial frequency intensity of a two-dimensional periodic structure having the pattern in FIG. 35A includes a component having a spatial frequency of 0 as a central point and points derived from the first periodic pattern Pa1 and the second periodic pattern Pa2 at equal distances from the central point. This results from the synthesis of two periodic patterns having the same period. The points derived from the first periodic pattern Pa1 and the second periodic pattern Pa2 are located on a concentric circle at regular intervals around the central point of the component having a spatial frequency of 0. A periodic pattern having the same structures on the grid points of a triangular grid composed of equilateral triangular unit cells forms six points in six directions from the central point. The six directions form an angle of 60 degrees with each other. When the period directions of such a periodic pattern form an angle of 30 degrees with each other, logical operation yields twelve points on a concentric circle. Thus, the number of directions of periodicity can be increased, and the light-emitting device can have improved directionality in more directions.

Although patterns are superposed using logical operation as described above, patterns may be superposed by another method. For example, when a submicron structure is formed in a photolithography process, a photomask is prepared for each pattern to be superposed, and a photoresist exposure process, a developing process, and an etching process using a resist layer as a mask can be performed multiple times to form a pattern composed of superposed patterns. Patterns are not necessarily superposed using a photoresist. After a first pattern is etched, a photoresist is applied again, and exposure to light, development, and etching using a resist layer as a mask may be performed. An increase in the number of masks results in an increased number of alignment errors and increased costs. Thus, it is desirable that the synthesized pattern be determined, for example, by logical operation.

Periodic structures may be formed on different layers (a photoluminescent layer and/or a light-transmissive layer (substrate)) or may be combined with the superposed pattern. For example, if three or more patterns are combined, two patterns may be a superposed pattern on one layer, and the other may be a pattern on another layer.

Depending on the pattern of a submicron structure formed of projections or recesses of a light-emitting device according to the present disclosure (periodic structures to be superposed), the distribution of spatial frequency intensity may include a point having a higher-order periodic structure. However, the periodic structure that contributes to improved directionality is a periodic structure corresponding to a point having high intensity near the central point.

### Stacking of Structures Having Different Periods

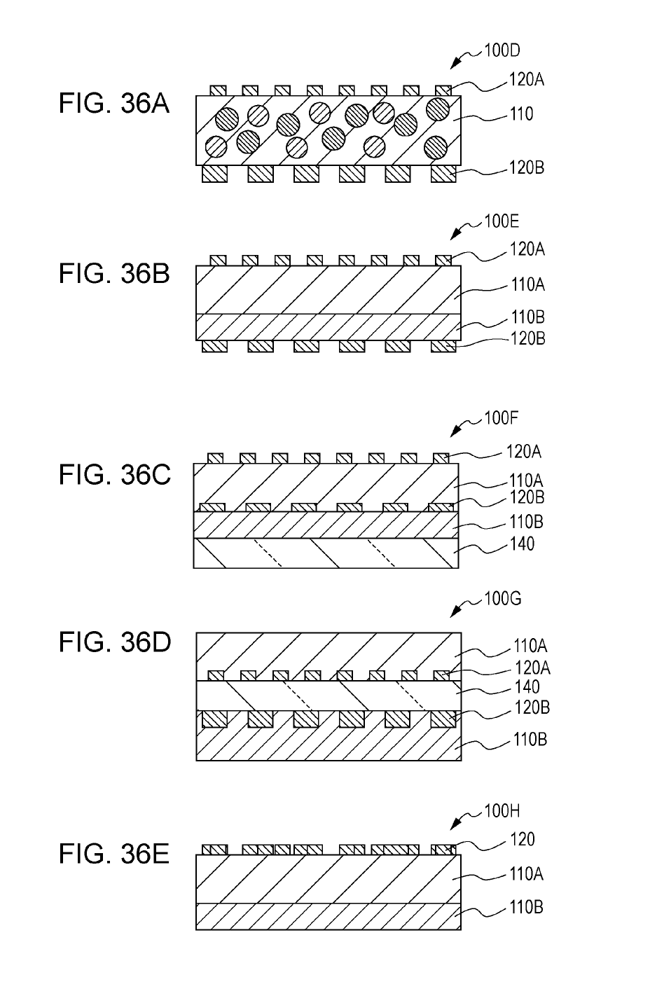

The structures of light-emitting devices 100D to 100H will be described below with reference to FIGS. 36A to 36E. In a photoluminescent layer of the light-emitting devices 100D to 100H, the emission wavelength λₐ of first light is different from the emission wavelength λ_{b} of second light, and the first period pₐ is different from the second period p_{b}. As a matter of course, a light-emitting device according to an embodiment of the present disclosure is not limited to these structures.

The light-emitting device 100D in FIG. 36A includes a photoluminescent layer 110 that contains photoluminescent materials having different emission wavelengths dispersed in a matrix, a first periodic structure 120A on a top surface of the photoluminescent layer 110, and a second periodic structure 120B on a bottom surface of the photoluminescent layer 110.

The light-emitting device 100E in FIG. 36B includes a photoluminescent layer composed of a photoluminescent layer 110A that has an emission wavelength of first light and a photoluminescent layer 110B that has an emission wavelength of second light and is in contact with a bottom surface of the photoluminescent layer 110A, a periodic structure 120A on a top surface of the photoluminescent layer 110A, and a periodic structure 120B on a bottom surface of the photoluminescent layer 110B. The periodic structures 120A and 120B may be independently formed of the material of the photoluminescent layers 110A and 110B, respectively, and may be formed as light-transmissive layers. It is desirable that the light-transmissive layers have a lower refractive index than the photoluminescent layer 110A or 110B.

The light-emitting device 100F in FIG. 36C includes another photoluminescent layer 110B in contact with a bottom surface of the photoluminescent layer 110A. In such a structure, one of the periodic structures may be located between the photoluminescent layers 110A and 110B. The periodic structure 120A may be formed of the material of the photoluminescent layer 110A and may be formed as a light-transmissive layer. It is desirable that the light-transmissive layer has a lower refractive index than the photoluminescent layer 110A. The periodic structure 120B may be formed of the material of the photoluminescent layer 110B and may be formed as a light-transmissive layer.

The light-emitting device 100G in FIG. 36D further includes, between the photoluminescent layers, a substrate 140 for supporting the photoluminescent layer 110A, and another photoluminescent layer 110B on a bottom surface of the substrate 140. Such a structure may include a periodic structure 120A on a top surface of the substrate 140 and a periodic structure 120B on a bottom surface of the substrate 140. The periodic structures 120A and 120B may be independently integral with the substrate 140 and may be formed as light-transmissive layers.

The light-emitting device 100H in FIG. 36E includes a periodic structure 120 formed by synthesizing a first periodic structure and a second periodic structure using logical operation. The method for synthesizing patterns may be combined with the structures described above.

### Synthesis of Structures Having Different Periods by Logic Synthesis

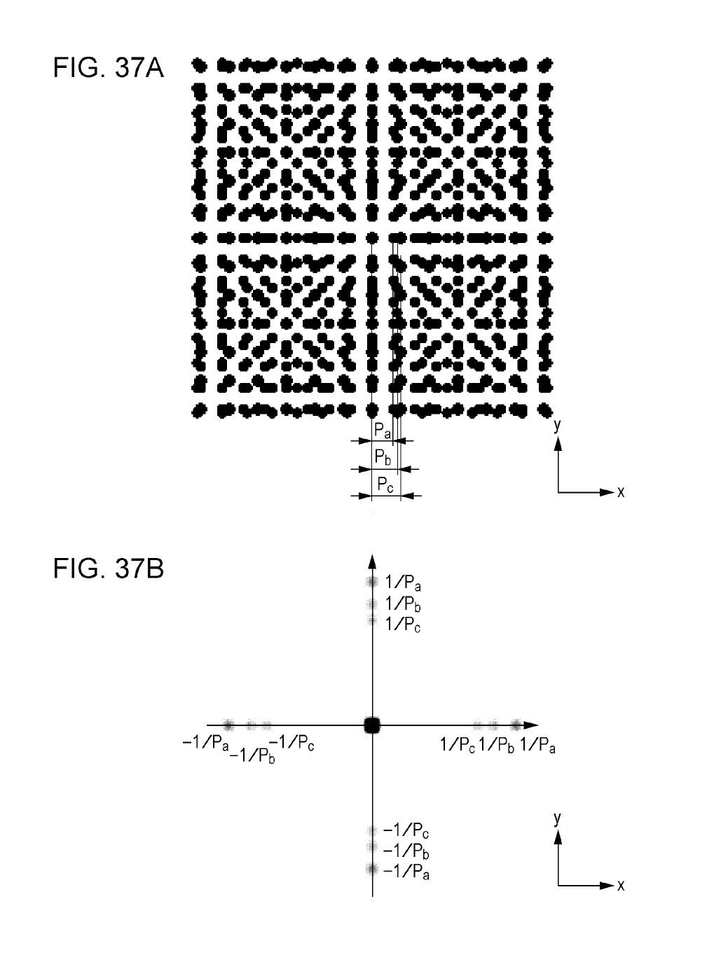

Next, refer to FIGS. 37A and 37B. FIG. 37A is a plan view of a pattern formed by synthesizing patterns of a two-dimensional periodic structure including periodic structures having different periods. FIG. 37B shows the distribution of spatial frequency intensity of the periodic structure obtained by Fourier transformation of the pattern in FIG. 37A.

The pattern of the two-dimensional periodic structure in FIG. 37A is obtained by superposition of square grid patterns having three different periods (pitches) Pₐ, P_{b}, and P_{c} while the periods have the same direction of periodicity (in the x direction and the y direction). The projection at each grid point is circular (cylindrical). The pattern in FIG. 37A is obtained as a logical sum of the three square grid patterns. For example, in each pattern, the projections are taken as “1 (true)”, and the recesses are taken as “0 (false)”. The operations of 1+0=1, 1+1=1, and 0+0=0 are performed in each point on the plane. As a matter of course, the logical operation for obtaining a pattern of superposed periodic structures is not limited to the logical sum and may be a logical product or logical difference. It is not necessary to match the grid positions, provided that the pattern has periodicity and the same direction of periodicity.

FIG. 37B illustrates the distribution of spatial frequency intensity of a two-dimensional periodic structure having the pattern in FIG. 37A. Points are formed at positions corresponding to three periodic structures (having periods Pₐ, P_{b}, and P_{c}) (that is, positions at distances of 1/Pₐ, 1/P_{b}, and 1/P_{c} from the central point). For example, the three periods may be adjusted so as to improve directionalities of red light, green light, and blue light in the same direction, so that a submicron structure on one layer can emit three light beams having different wavelengths in a particular direction. These three color light beams can be superposed to emit white light in a particular direction.

Although the directionalities of red light, green light, and blue light are improved by way of example, the wavelength may be any wavelength. Photoluminescent materials may be efficiently excited by interference with excitation light.

Such a submicron structure having periodic structures may be formed on a photoluminescent layer, on a light-transmissive layer, or at the interface between a photoluminescent layer and a light-transmissive layer (on both of the layers). Furthermore, in a structure including a substrate, the substrate may have a submicron structure.

The material of a photoluminescent layer may be a material that emits white light. For example, a photoluminescent layer that emits blue light may be located on a photoluminescent layer that emits yellow light. Alternatively, a photoluminescent layer may contain photoluminescent materials that emit light beams of different colors.

Light-emitting devices and light-emitting apparatuses according to the present disclosure can be applied to various optical devices, such as lighting fixtures, displays, and projectors.

What is claimed is:

1. A light-emitting device comprising:
a photoluminescent layer that has a first surface perpendicular to a thickness direction thereof and emits light containing first light and second light, an area of the first surface being larger than a sectional area of the photoluminescent layer perpendicular to the first surface; and
a light-transmissive layer located on the photoluminescent layer, wherein
at least one of the photoluminescent layer and the light-transmissive layer has a submicron structure including at least two periodic structures having at least projections or recesses arranged perpendicular to the thickness direction of the photoluminescent layer,
at least one of the photoluminescent layer and the light-transmissive layer has a light emitting surface perpendicular to the thickness direction of the photoluminescent layer, the first light and the second light being emitted from the light emitting surface,
the first light has a wavelength λₐ in air,
the second light has a wavelength λ_{b} in air,
the at least two periodic structures include a first periodic structure having a first period pₐ that satisfies λₐ/n_{wav-a}<pₐ<λₐ and a second periodic structure having a second period p_{b} that satisfies λ_{b}/n_{wav-b}<p_{b}<λ_{b}, where n_{wav-a} and n_{wav-b} denote refractive indices of the photoluminescent layer for the first light and the second light, respectively, and
a thickness of the photoluminescent layer, the refractive indexes n_{wav-a} and n_{wav-b}, and the first and second periods pₐ and p_{b} are set to limit directional angles of the first and second light emitted from the light emitting surface.

2. The light-emitting device according to claim 1, wherein the wavelength λₐ of the first light is equal to the wavelength λ_{b} of the second light, the first period pₐ is equal to the second period p_{b}, and the first periodic structure has a different direction of periodicity from the second periodic structure.

3. The light-emitting device according to claim 1, wherein the first period pₐ is different from the second period p_{b}, and the first periodic structure and the second periodic structure have the same direction of periodicity.

4. The light-emitting device according to claim 1, wherein the first periodic structure and the second periodic structure are located on the same surface of the at least one of the photoluminescent layer and the light-transmissive layer.

5. The light-emitting device according to claim 1, wherein one of the first periodic structure and the second periodic structure is located on a top surface of the photoluminescent layer, and the other is located on a bottom surface of the photoluminescent layer.

6. The light-emitting device according to claim 1, further comprising
an additional photoluminescent layer in contact with a bottom surface of the photoluminescent layer,
wherein one of the first periodic structure and the second periodic structure is located on a top surface of the photoluminescent layer, and the other is located on a bottom surface of the additional photoluminescent layer.

7. The light-emitting device according to claim 1, further comprising
an additional photoluminescent layer in contact with a bottom surface of the photoluminescent layer,
wherein one of the first periodic structure and the second periodic structure is located on a top surface of the photoluminescent layer, and the other is located on a top surface of the additional photoluminescent layer.

8. The light-emitting device according to claim 1, further comprising:
a substrate for supporting the photoluminescent layer; and an additional photoluminescent layer on a bottom surface of the substrate,
wherein one of the first periodic structure and the second periodic structure is located on a top surface of the substrate, and the other is located on the bottom surface of the substrate.

9. A light-emitting device comprising:
a photoluminescent layer that has a first surface perpendicular to a thickness direction thereof and emits light containing first light and second light, an area of the first surface being larger than a sectional area of the photoluminescent layer perpendicular to the first surface; and
a light-transmissive layer located on the photoluminescent layer, wherein
at least one of the photoluminescent layer and the light-transmissive layer has a submicron structure having projections or recesses arranged perpendicular to the thickness direction of the photoluminescent layer,
at least one of the photoluminescent layer and the light-transmissive layer has a light emitting surface perpendicular to the thickness direction of the photoluminescent layer, the first light and the second light being emitted from the light emitting surface,
a distribution of spatial frequency intensity obtained by Fourier transformation of a two-dimensional pattern of height of the projections or the recesses includes at least two pairs of two points located at point-symmetrical positions with respect to a central point,
the at least two pairs include a pair of two points at a distance of 1/pₐ from the central point and another pair of two points at a distance of 1/p_{b} from the central point,
the first light has a wavelength λₐ in air and the second light has a wavelength λ_{b} in air,
the photoluminescent layer has refractive indices n_{wav-a} and n_{wav-b} for the first light and the second light, respectively, that satisfy λₐ/n_{wav-a}<pₐ<λₐ and λ_{b}/n_{wav-b}<p_{b}<λ_{b}, and
a thickness of the photoluminescent layer, the refractive indexes n_{wav-a} and n_{wav-b}, and the first and second periods pₐ and p_{b} are set to limit directional angles of the first and second light emitted from the light emitting surface.

10. The light-emitting device according to claim 9, wherein the at least two pairs include two pairs having the same distance from the central point.

11. The light-emitting device according to claim 9, wherein the at least two pairs include two pairs having different distances from the central point.

12. The light-emitting device according to claim 9, wherein the submicron structure is located on the same surface of the at least one of the photoluminescent layer and the light-transmissive layer.

13. A light-emitting device comprising:
a light-transmissive layer having a submicron structure; and
a photoluminescent layer that is located on the submicron structure, has a first surface perpendicular to a thickness direction thereof, and emits light containing first light and second light, an area of the first surface being larger than a sectional area of the photoluminescent layer perpendicular to the first surface, wherein
the submicron structure includes at least two periodic structures having at least projections or recesses arranged perpendicular to the thickness direction of the photoluminescent layer,
at least one of the photoluminescent layer and the light-transmissive layer has a light emitting surface perpendicular to the thickness direction of the photoluminescent layer, the first light and the second light being emitted from the light emitting surface,
the first light has a wavelength λₐ in air,
the second light has a wavelength λ_{b} in air,
the at least two periodic structures include a first periodic structure having a first period pₐ that satisfies λₐ/n_{wav-a}<pₐ<λₐ and a second periodic structure having a second period p_{b} that satisfies λ_{b}/n_{wav-b}<p_{b}<λ_{b}, where n_{wav-a} and n_{wav-b} denote refractive indices of the photoluminescent layer for the first light and the second light, respectively, and
a thickness of the photoluminescent layer, the refractive indexes n_{wav-a} and n_{wav-b}, and the first and second periods pₐ and p_{b} are set to limit directional angles of the first and second light emitted from the light emitting surface.

14. A light-emitting device comprising:
a photoluminescent layer that has a first surface perpendicular to a thickness direction thereof and emits light containing first light and second light, an area of the first surface being larger than a sectional area of the photoluminescent layer perpendicular to the first surface; and
a light-transmissive layer having a higher refractive index than the photoluminescent layer, wherein
the light-transmissive layer has a submicron structure including at least two periodic structures having at least projections or recesses arranged perpendicular to the thickness direction of the photoluminescent layer,
at least one of the photoluminescent layer and the light-transmissive layer has a light emitting surface perpendicular to the thickness direction of the photoluminescent layer, the first light and the second light being emitted from the light emitting surface,
the first light has a wavelength λₐ in air,
the second light has a wavelength λ_{b} in air,
the at least two periodic structures include a first periodic structure having a first period pₐ that satisfies λₐ/n_{wav-a}<pₐ<λₐ and a second periodic structure having a second period p_{b} that satisfies λ_{b}/n_{wav-b}<p_{b}<λ_{b}, where n_{wav-a} and n_{wav-b} denote refractive indices of the photoluminescent layer for the first light and the second light, respectively, and
a thickness of the photoluminescent layer, the refractive indexes n_{wav-a} and n_{wav-b}, and the first and second periods pₐ and p_{b} are set to limit directional angles of the first and second light emitted from the light emitting surface.

15. The light-emitting device according to claim 1, wherein the photoluminescent layer is in contact with the light-transmissive layer.

16. A light-emitting device comprising:
a photoluminescent layer that has a first surface perpendicular to a thickness direction thereof and emits light containing first light and second light, an area of the first surface being larger than a sectional area of the photoluminescent layer perpendicular to the first surface, wherein
the photoluminescent layer has a submicron structure including at least two periodic structures having at least projections or recesses arranged perpendicular to the thickness direction of the photoluminescent layer,
the photoluminescent layer has a light emitting surface perpendicular to the thickness direction of the photoluminescent layer, the first light being emitted from the light emitting surface,
the first light has a wavelength λₐ in air,
the second light has a wavelength λ_{b} in air,
the at least two periodic structures include a first periodic structure having a first period pₐ that satisfies λₐ/n_{wav-a}<pₐ<λₐ and a second periodic structure having a second period p_{b} that satisfies λ_{b}/n_{wav-b}<p_{b}<λ_{b}, where n_{wav-a} and n_{wav-b} denote refractive indices of the photoluminescent layer for the first light and the second light, respectively, and
a thickness of the photoluminescent layer, the refractive indexes n_{wav-a} and n_{wav-b}, and the first and second periods pₐ and p_{b} are set to limit directional angles of the first and second light emitted from the light emitting surface.

17. The light-emitting device according to claim 1, wherein the submicron structure has both the projections and the recesses.

18. A light-emitting apparatus comprising:
ht-emitting device according to claim 1; and
an excitation light source for irradiating the photoluminescent layer with excitation light.

19. The light-emitting device according to claim 1, wherein the photoluminescent layer includes a phosphor.

20. The light-emitting device according to claim 1, wherein 380 nm≦λₐ≦780 nm and 380 nm≦λ_{b}≦780 nm are satisfied.

21. The light-emitting device according to claim 1, wherein the thickness of the photoluminescent layer, the refractive indexes n_{wav-a} and n_{wav-b}, and the first and second periods pₐ and p_{b} are set to allow an electric field to be formed in the photoluminescent layer, in which antinodes of the electric field are located in areas, the areas each corresponding to respective one of the projections and/or recesses.

22. The light-emitting device according to claim 1, wherein the light-transmissive layer is located indirectly on the photoluminescent layer.

23. The light-emitting device according to claim 1, wherein the thickness of the photoluminescent layer, the refractive indexes n_{wav-a} and n_{wav-b}, and the first and second periods pₐ and p_{b} are set to allow an electric field to be formed in the photoluminescent layer, in which antinodes of the electric field are located at, or adjacent to, at least the projections or recesses.

24. The light-emitting device according to claim 1, further comprising a substrate that has a refractive index nₛ₋ₐ for the first light and a refractive index n_{s-b} for the second light is located on the photoluminescent layer, wherein λₐ/n_{wav-a}<pₐ<λₐ/nₛ₋ₐ and λ_{b}/n_{wav-b}<p_{b}<λ_{b}/n_{s-b} are satisfied.
